(19) United States
(12) Patent Application Publication
(10) Pub. No.: US 2018/0248078 A1
(43) Pub. Date: Aug. 30, 2018

(54) LIGHT-EMITTING DIODE CHIP

(71) Applicant: Genesis Photonics Inc., Tainan City (TW)

(72) Inventors: Yu-Chen Kuo, Tainan City (TW); Teng-Hsien Lai, Tainan City (TW); Kai-Shun Kang, Tainan City (TW); Yan-Ting Lan, Tainan City (TW); Jing-En Huang, Tainan City (TW); Cheng-Pin Chen, Tainan City (TW); Wei-Chen Chien, Tainan City (TW); Chih-Chin Cheng, Tainan City (TW); Chih-Hung Tseng, Tainan City (TW)

(21) Appl. No.: 15/965,999

(22) Filed: Apr. 30, 2018

Related U.S. Application Data
(63) Continuation of application No. 15/135,574, filed on Apr. 22, 2016, now abandoned.
Application No. 15/135,574 is a continuation-in-part of application No. 15/045,263, filed on Feb. 17, 2016, now abandoned.
(60) Provisional application No. 62/116,923, filed on Feb. 17, 2015.
(60) Provisional application No. 62/151,377, filed on Apr. 22, 2015.
(60) Provisional application No. 62/213,592, filed on Sep. 2, 2015.

(51) Int. Cl. H01L 33/38; H01L 33/14

(52) U.S. Cl. CPC H01L 33/38; H01L 33/145

(57) ABSTRACT

Provided is a light-emitting diode chip including a semiconductor device layer, a first electrode, a current-blocking layer, a current-spreading layer, and a second electrode. The semiconductor device layer includes a first-type doped semiconductor layer, a second-type doped semiconductor layer, and a light-emitting layer therebetween. The first electrode is electrically connected to the first-type doped semiconductor layer. The current-blocking layer is on the second-type doped semiconductor layer. The current-blocking layer is between the current-spreading layer and the second-type doped semiconductor layer. The second electrode is on the current-spreading layer and electrically connected to the second-type doped semiconductor layer. The current-blocking layer has a first surface facing the semiconductor device layer, a second surface back on to the semiconductor device layer, and a first inclined surface. The first inclined surface is connected between the first surface and the second surface and tilted with respect to the first surface and the second surface.

### CROSS-REFERENCE TO RELATED APPLICATION

This application is a continuation application of and claims the priority benefit of U.S. application Ser. No. 15/135,574, filed on Apr. 22, 2016, now pending. The prior application Ser. No. 15/135,574 is a continuation-in-part application of and claims the priority benefit of U.S. application Ser. No. 15/045,263, filed on Feb. 17, 2016, now pending. The prior U.S. application Ser. No. 15/045,263 claims the priority benefits of U.S. provisional application Ser. No. 62/116,923, filed on Feb. 17, 2015, U.S. provisional application Ser. No. 62/151,377, filed on Apr. 22, 2015, and U.S. provisional application Ser. No. 62/213,592, filed on Sep. 2, 2015. The entirety of each of the above-mentioned patent applications is hereby incorporated by reference herein and made a part of this specification.

### BACKGROUND OF THE INVENTION

### 1. Field of the Invention

The invention relates to a light-emitting device, and more particularly, to a light-emitting diode (LED) chip.

### 2. Description of Related Art

With the advancement in semiconductor techniques, the current light-emitting diode now has characteristics such as high brightness and high color rendering properties. Moreover, the light-emitting diode has advantages such as power saving, small size, low voltage drive, and lack of mercury, and therefore the light-emitting diode is extensively applied in areas such as display and illumination. In general, the luminous efficiency of the light-emitting diode chip and the internal quantum efficiency (i.e., light-extraction efficiency) of the light-emitting diode chip are related. When the light emitted by the light-emitting layer has a greater ratio for passing through the light-emitting diode chip, the internal quantum efficiency of the light-emitting diode chip is better. The electrode of the light-emitting diode chip is generally made from a metal material, and due to the opacity of the metal material, the light emitted by the region covered by the electrode on the light-emitting diode chip cannot be effectively utilized. As a result, energy waste occurs. Therefore, a technique of manufacturing a current-blocking layer between an electrode and a semiconductor device layer has been developed. However, increasing the luminous efficiency of a light-emitting diode chip via the current-blocking layer still has much room for improvement. Therefore, how to further improve the performance of the LED chip is a current focus for research and development personnel.

### SUMMARY OF THE INVENTION

The present invention provides the light-emitting diode chips having good performance.

The present invention provides a light-emitting diode chip including a semiconductor device layer, a first electrode, a current-blocking layer, a current-spreading layer, and a second electrode. The semiconductor device layer includes a first-type doped semiconductor layer, a second-type doped semiconductor layer, and a light-emitting layer located between the first-type and second-type doped semiconductor layers. The first electrode is electrically connected to the first-type doped semiconductor layer. The current-blocking layer is disposed on the second-type doped semiconductor layer. The current-blocking layer is sandwiched between the current-spreading layer and the second-type doped semiconductor layer. The second electrode is disposed on the current-spreading layer and electrically connected to the second-type doped semiconductor layer. The current-blocking layer has a first surface facing or front-facing the semiconductor device layer, a second surface back on to the semiconductor device layer, and a first inclined surface. The first inclined surface is connected between the first surface and the second surface and tilted with respect to the first surface and the second surface.

The present invention provides another light-emitting diode chip including a semiconductor device layer, a first electrode, a current-blocking layer, a current-spreading layer, and a second electrode. The semiconductor device layer includes a first-type doped semiconductor layer, a light-emitting layer, and a second-type doped semiconductor layer. The light-emitting layer is located between the first-type doped semiconductor layer and the second-type doped semiconductor layer. The first electrode is electrically connected to the first-type doped semiconductor layer. The current-blocking layer is disposed on the second-type doped semiconductor layer. The current-blocking layer includes at least one first current-blocking sub-layer and at least one second current-blocking sub-layer. The at least one first current-blocking sub-layer is stacked with the at least one second current-blocking sub-layer. The current-blocking layer is disposed between the current-spreading layer and the second-type doped semiconductor layer. The second electrode is electrically connected to the second-type doped semiconductor layer.

Based on the above, the current-blocking layer of the light-emitting diode chip has an inclined surface in an embodiment of the present invention. In such a way, the coverage of the current-spreading layer proximate to the inclined surface will be good when the current-spreading layer covers the current-blocking layer, so as to improve the performance of the light-emitting diode chip. In addition, the current-spreading layer includes a reflective layer in another embodiment of the present invention. In such a way, the light beam emitted by the light-emitting layer and traveling toward the electrode can be reflected to other places by the current-spreading layer, so that the light beam emitted by the light-emitting layer is not easily blocked by the electrode having shielding effect and capable of emitting out at other places consequently, which facilitates to enhance the brightness of the light-emitting diode chip.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are cross-sectional views of light-emitting diode chips according to the first embodiment of the invention.

FIG. 2A to FIG. 2E are top views of different light-emitting diode chips according to the first embodiment of the invention.

FIG. 3A to FIG. 3C are top views of different light-emitting diode chips according to the second embodiment of the invention.

FIG. 4A to FIG. 4B are cross-sectional views of different light-emitting diode chips according to the third embodiment of the invention.

FIG. 5A to FIG. 5D are flowcharts of the manufacturing method of the light-emitting diode chip of the embodiment of FIG. 4A.

FIG. 6A to FIG. 6B are top views of different light-emitting diode chips according to the fourth embodiment of the invention.

FIG. 7A is a top view of the light-emitting diode chip according to the fifth embodiment of the invention.

FIG. 7B is a cross-sectional view of the light-emitting diode chip of FIG. 7A along line A-A′.

FIG. 7C to FIG. 7F, FIG. 7G to FIG. 7J, and FIG. 7K to FIG. 7M are flowcharts of the manufacturing method of different light-emitting diode chips according to the sixth embodiment of the invention.

FIG. 8A is a top view of the light-emitting diode chip according to the seventh embodiment of the invention.

FIG. 8B is a cross-sectional view of the light-emitting diode chip of FIG. 8A along line B-B′.

FIG. 9A is a top view of the light-emitting diode chip according to the eighth embodiment of the invention.

FIG. 9B is a cross-sectional view of the light-emitting diode chip of FIG. 9A along line C-C′.

FIG. 10A is a top view of the light-emitting diode chip according to the ninth embodiment of the invention.

FIG. 10B is a cross-sectional view of the light-emitting diode chip of FIG. 10A along line D-D′.

FIG. 10C to FIG. 10F are flowcharts of the manufacturing method of the light-emitting diode chip of the embodiment of FIG. 10A.

FIG. 11A is a top view of the light-emitting diode chip according to the tenth embodiment of the invention.

FIG. 11B is a cross-sectional view of the light-emitting diode chip of FIG. 11A along line E-E′.

FIG. 12A is a top view of the light-emitting diode chip according to the eleventh embodiment of the invention.

FIG. 12B is a cross-sectional view of the light-emitting diode chip of FIG. 12A along line F-F′.

FIG. 13A is a top view of the light-emitting diode chip according to the twelfth embodiment of the invention.

FIG. 13B is a cross-sectional view of the light-emitting diode chip of FIG. 13A along line G-G′.

FIG. 14A is a top view of the light-emitting diode chip according to the thirteenth embodiment of the invention.

FIG. 14B is a cross-sectional view of the light-emitting diode chip of FIG. 14A along line H-H′.

FIG. 15A is a top view of the light-emitting diode chip according to the fourteenth embodiment of the invention.

FIG. 15B is a cross-sectional view of the light-emitting diode chip of FIG. 15A along line I-I′.

FIG. 16A is a top view of the light-emitting diode chip according to the fifteenth embodiment of the invention.

FIG. 16B is a cross-sectional view of the light-emitting diode chip of FIG. 16A along line J-J′.

FIG. 17A is a top view of the light-emitting diode chip according to the sixteenth embodiment of the invention.

FIG. 17B is a cross-sectional view of the light-emitting diode chip of FIG. 17A along line K-K′.

FIG. 18A is a top view of the light-emitting diode chip according to the seventeenth embodiment of the invention.

FIG. 18B is a cross-sectional view of the light-emitting diode chip of FIG. 18A along line L-L′.

FIG. 19A to FIG. 19C are cross-sectional views of various light-emitting diode chips according to the eighteenth embodiment of the invention.

FIG. 20 is an enlarged view of the second-type doped semiconductor layer, current-blocking layer, and current-spreading layer of an embodiment of the invention.

FIG. 21 is an enlarged view of the second-type doped semiconductor layer, current-blocking layer, and current-spreading layer of a comparative example of the invention.

FIG. 22A is an enlarged view of the current-blocking layer of an embodiment of the invention.

FIG. 22B is an enlarged view of the current-blocking layer of another embodiment of the invention.

FIG. 23A is a top view of the light-emitting diode chip according to the nineteenth embodiment of the invention.

FIG. 23B is a cross-sectional view of the light-emitting diode chip of FIG. 23A along line A-A′.

FIG. 24A is a top view of the light-emitting diode chip according to the twentieth embodiment of the invention.

FIG. 24B is a cross-sectional view of the light-emitting diode chip of FIG. 24A along line B-B′.

FIG. 25A is a top view of the light-emitting diode chip according to the twenty first embodiment of the invention.

FIG. 25B is a cross-sectional view of the light-emitting diode chip of FIG. 25A along line D-D′.

FIG. 26A is a top view of the light-emitting diode chip according to the twenty second embodiment of the invention.

FIG. 26B is a cross-sectional view of the light-emitting diode chip of FIG. 26A along line E-E′.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

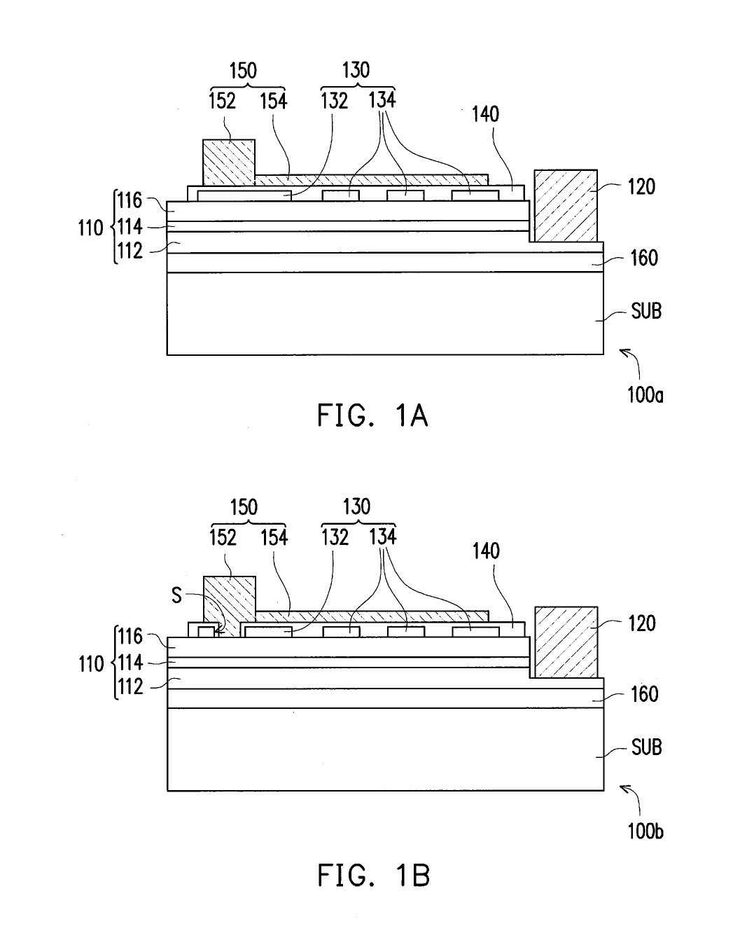

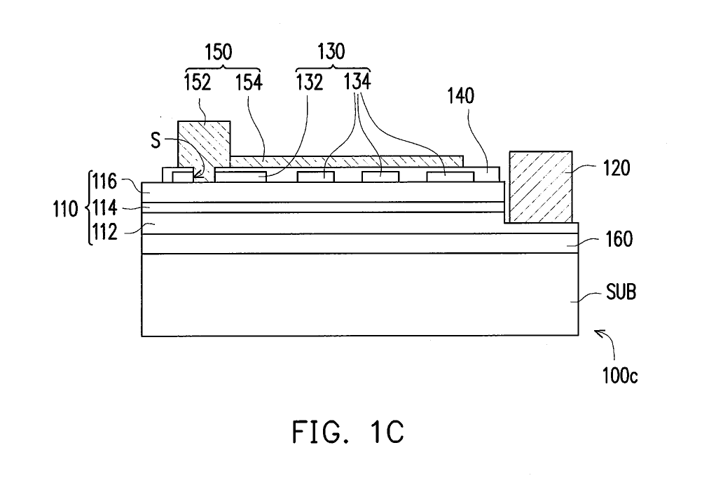

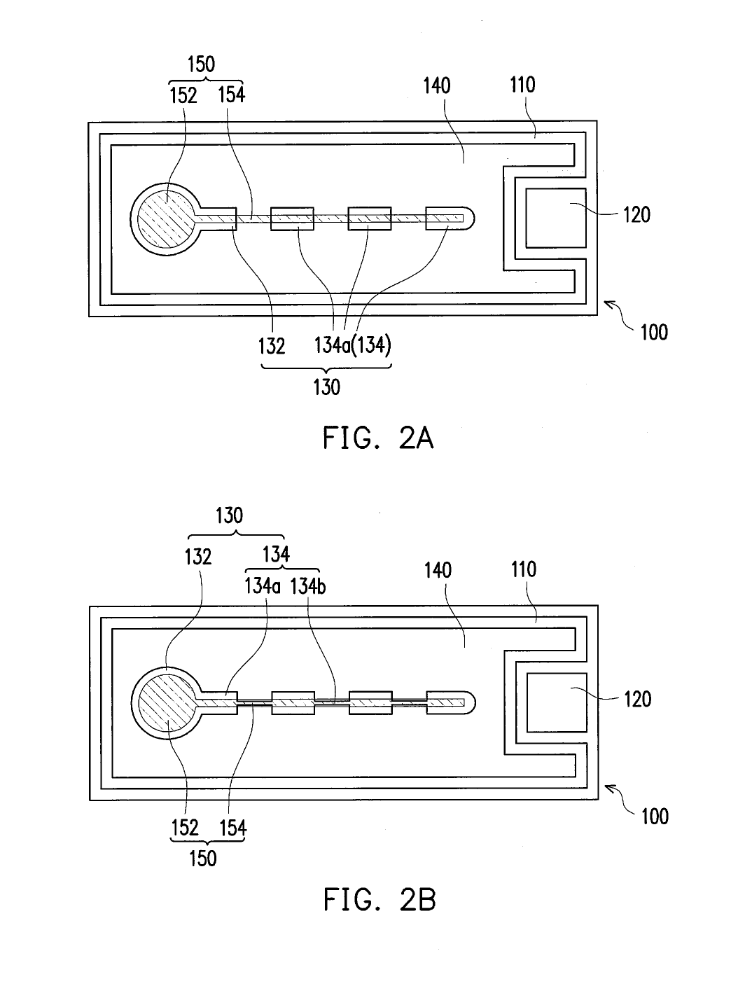

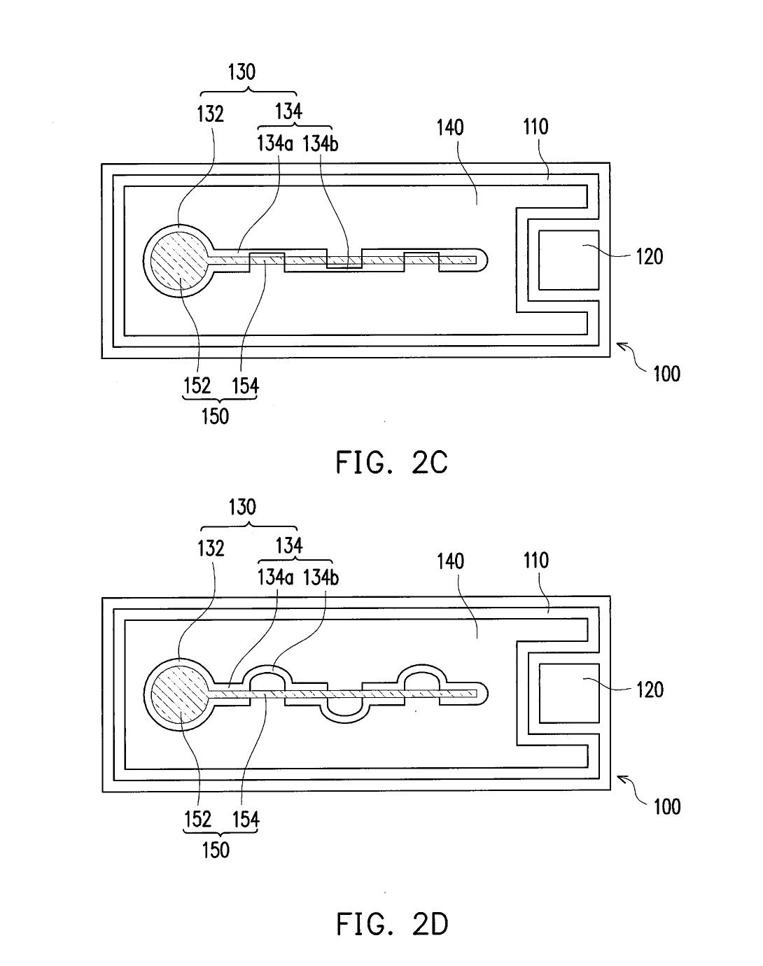

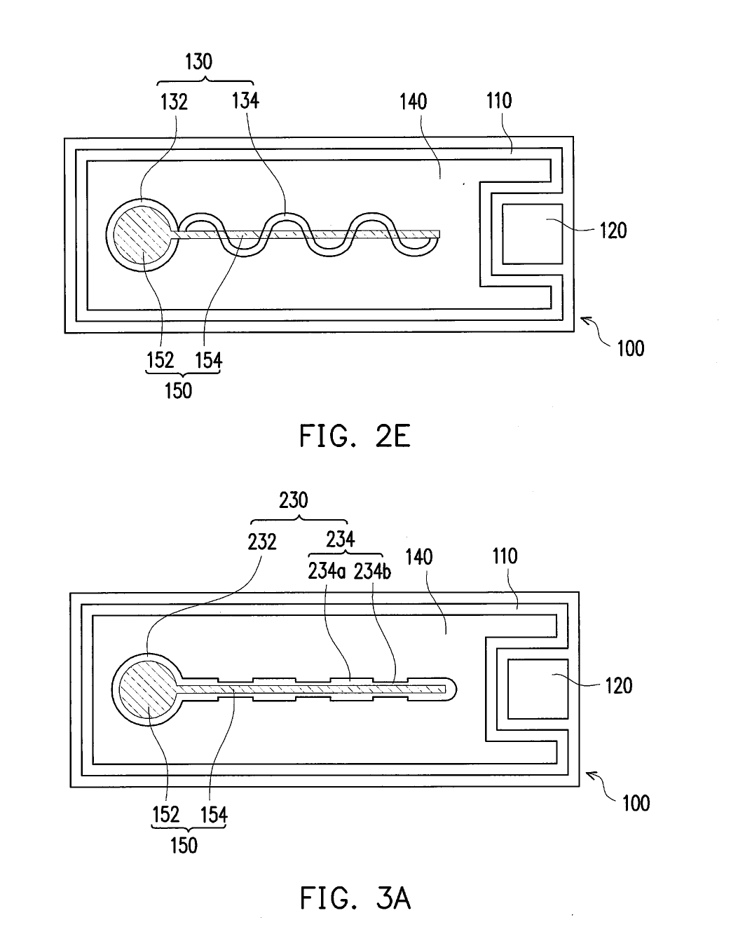

FIG. 1A to FIG. 1C are cross-sectional views of a light-emitting diode chip according to the invention, and FIG. 2A to FIG. 2E are top views of different light-emitting diode chips according to the first embodiment of the invention.

Referring to FIG. 1A, a light-emitting diode chip 100a of the present embodiment includes a semiconductor device layer 110, a first electrode 120, a current-blocking layer 130, a current-spreading layer 140, and a second electrode 150. The semiconductor device layer 110 includes a first-type doped semiconductor layer 112, a light-emitting layer 114, and a second-type doped semiconductor layer 116, wherein the light-emitting layer 114 is located between the first-type doped semiconductor layer 112 and the second-type doped semiconductor layer 116. The first electrode 120 is electrically connected to the first-type doped semiconductor layer 112. The current-blocking layer 130 is disposed on the second-type doped semiconductor layer 116, and the current-blocking layer 130 includes a main body 132 and an extending portion 134 extended from the main body 132. The current-spreading layer 140 is disposed on the second-type doped semiconductor layer 116 to cover the current-blocking layer 130. The second electrode 150 is electrically connected to the second-type doped semiconductor layer 116 via the current-spreading layer 140, wherein the second electrode 150 includes a bond pad 152 and a finger portion 154 extended from the bond pad 152, the bond pad 152 is located above the main body 132, the finger portion 154 is located above the extending portion 134, and a partial region of the finger portion 154 is not overlapped with the extending portion 134.

Referring to FIG. 1B, the main difference between a light-emitting diode chip 100b in FIG. 1B and the light-emitting diode chip 100a of the above embodiment is: the bond pad 152 passes through the current-spreading layer 140 and the main body 132, and the bond pad 152 is in contact with the second-type doped semiconductor layer 116, wherein the current-spreading layer 140 covers a sidewall S of the main body 132 that the bond pad 152 passes through.

Referring to FIG. 1C, the main difference between a light-emitting diode chip 100c in FIG. 1C and the light-emitting diode chip 100b of the above embodiment is: the current-spreading layer 140 does not cover the sidewall S of the main body 132 that the bond pad 152 passes through. In other words, the bond pad 152 passing through the current-spreading layer 140 and the main body 132 is directly in contact or connected with the sidewall S of the main body 132.

Since a partial region of the finger portion 154 is not overlapped with the extending portion 134 of the current-blocking layer 130, the driving current applied to the second electrode 150 can be readily transmitted to the semiconductor device layer 110 via the regions (i.e., current-collecting regions) not overlapped with the extending portion 134. In other words, in the present embodiment, the location of the current-collecting regions in the light-emitting diode chip 100 can be controlled via the pattern designs of the extending portion 134 and the finger portion 154 and the overlapping condition of the two, so as to improve the luminous efficiency of the light-emitting diode chip 100.

In the present embodiment, the light-emitting layer 114 is disposed on the first-type doped semiconductor layer 112 to expose a portion of the first-type doped semiconductor layer 112, and the first electrode 120 is disposed on the portion of the first-type doped semiconductor layer 112 exposed by the light-emitting layer 114. In other words, the light-emitting diode chip 100 of the present embodiment is a horizontal-type light-emitting diode chip. For instance, the first-type doped semiconductor layer 112 in the semiconductor device layer 110 is, for instance, an N-type doped semiconductor layer, the second-type doped semiconductor layer 116 is, for instance, a P-type doped semiconductor layer, and the light-emitting layer 114 is, for instance, a multiple quantum well (MQW) formed by a plurality of alternately-stacked well layers and barrier layers. Moreover, the semiconductor device layer 110 of the present embodiment is, for instance, manufactured on a substrate SUB via an epitaxial process, and the substrate SUB can be, for instance, a sapphire substrate, a silicon substrate, or a silicon carbide substrate.

It should be mentioned that, the above semiconductor device layer 110 can further include a buffer layer 160, and the buffer layer 160 is generally formed on the substrate SUB before the manufacture of the first-type doped semiconductor layer 112. In other words, the buffer layer 160 can be optionally formed between the substrate SUB and the semiconductor device layer 110 to provide suitable stress relief and improve the epitaxial quality of a subsequently-formed thin film.

In the present embodiment, the first electrode 120 is, for instance, a metal material having good Ohmic contact with the first-type doped semiconductor layer 112, the material of the current-blocking layer 130 is, for instance, a dielectric layer, the material of the current-spreading layer 140 is, for instance, a transparent conducting material, and the second electrode 150 is, for instance, a metal material having good Ohmic contact with the current-spreading layer 140. For instance, the material of the first electrode 120 includes a conducting material such as chromium (Cr), gold (Au), aluminum (Al), or titanium (Ti), the material of the current-blocking layer 130 includes a dielectric material such as silicon oxide (SiOx) or silicon nitride (SiNx), the material of the current-spreading layer 140 includes a transparent conducting material such as indium-tin-oxide (ITO) or indium-zinc-oxide (IZO); and the material of the second electrode 150 includes a conducting material such as Cr, Au, Al, or Ti.

The current-blocking layer 130 of the present embodiment can adopt different designs, and in the following, different designs of the current-blocking layer 130 are described with reference to FIG. 2A to FIG. 2E.

As shown in FIG. 2A, the extending portion 134 of the present embodiment can include a plurality of current-blocking patterns 134a separated from one another, and the current-blocking patterns 134a are arranged along the extending direction of the finger portion 154. For instance, the current-blocking patterns 134a are block patterns. It can be known from FIG. 2A that, the current-blocking patterns 134a separated from one another can effectively block current from the finger portion 154, and regions between adjacent current-blocking patterns 134a can be regarded as regions of current collection. It should be mentioned that, the spacing between any two adjacent current-blocking patterns 134a can be suitably changed according to actual design requirements to adjust the size of the current-collecting regions.

As shown in FIG. 2B, the extending portion 134 of the present embodiment can include a plurality of current-blocking patterns 134a and a plurality of connecting patterns 134b arranged along the extending direction of the finger portion 154, wherein any two adjacent current-blocking patterns 134a are connected to each other via the corresponding connecting pattern 134b. The connecting patterns 134b are partially overlapped with the finger portion 154, and the width of each of the connecting patterns 134b along the extending direction of the finger portion 154 is less than the width of the finger portion 154. For instance, the current-blocking patterns 134a are block patterns, and the connecting patterns 134b are stripe patterns. It can be known from FIG. 2B that, the above current-blocking patterns 134a can effectively block current from the finger portion 154, and since the connecting patterns 134b are partially overlapped with the finger portion 154, the connecting patterns 134b can still partially block current from the finger portion 154, and the surrounding region of the connecting patterns 134b can be regarded as a region of current collection.

As shown in FIG. 2C, the extending portion 134 of the present embodiment can include a plurality of current-blocking patterns 134a and a plurality of connecting patterns 134b arranged along the extending direction of the finger portion 154, wherein any two adjacent current-blocking patterns 134a are connected to each other via the corresponding connecting pattern 134b. The connecting patterns 134b are not overlapped with the finger portion 154, and the width of each of the connecting patterns 134b along the extending direction of the finger portion 154 is less than the width of the finger portion 154. For instance, the current-blocking patterns 134a are block patterns, and the connecting patterns 134b are stripe patterns. It can be known from FIG. 2C that, the above current-blocking patterns 134a can effectively block current from the finger portion 154, and the blocking effect of the connecting patterns 134b against current from the finger portion 154 is less significant, and therefore the region between adjacent current-blocking patterns 134a can be regarded as a region of current collection.

As shown in FIG. 2D, the extending portion 134 of the present embodiment similarly can include a plurality of current-blocking patterns 134a and a plurality of connecting patterns 134b arranged along the extending direction of the finger portion 154, wherein any two adjacent current-blocking patterns 134a are connected to each other via the corresponding connecting pattern 134b. However, the connecting patterns 134b in FIG. 2C are not overlapped with the finger portion 154. For instance, the current-blocking patterns 134a are block patterns, and the connecting patterns 134b are arc patterns. It can be known from FIG. 2C that, the above current-blocking patterns 134a can effectively block current from the finger portion 154, and the blocking effect of the connecting patterns 134b against current from the finger portion 154 is less significant, and therefore the region between adjacent current-blocking patterns 134a can be regarded as a region of current collection.

As shown in FIG. 2E, the extending portion 134 of the present embodiment can be a wave pattern, and the wave pattern has a plurality of intersections with the finger portion 154. It should be mentioned that, at the intersections of the wave pattern and the finger portion 154, current from the finger portion 154 is not effectively blocked. However, at other locations of the finger portion 154, the blocking effect of the connecting patterns 134b against current from the finger portion 154 is less significant, and therefore except for the intersections of the wave pattern and the finger portion 154, the other locations can all be regarded as regions of current collection.

### Second Embodiment

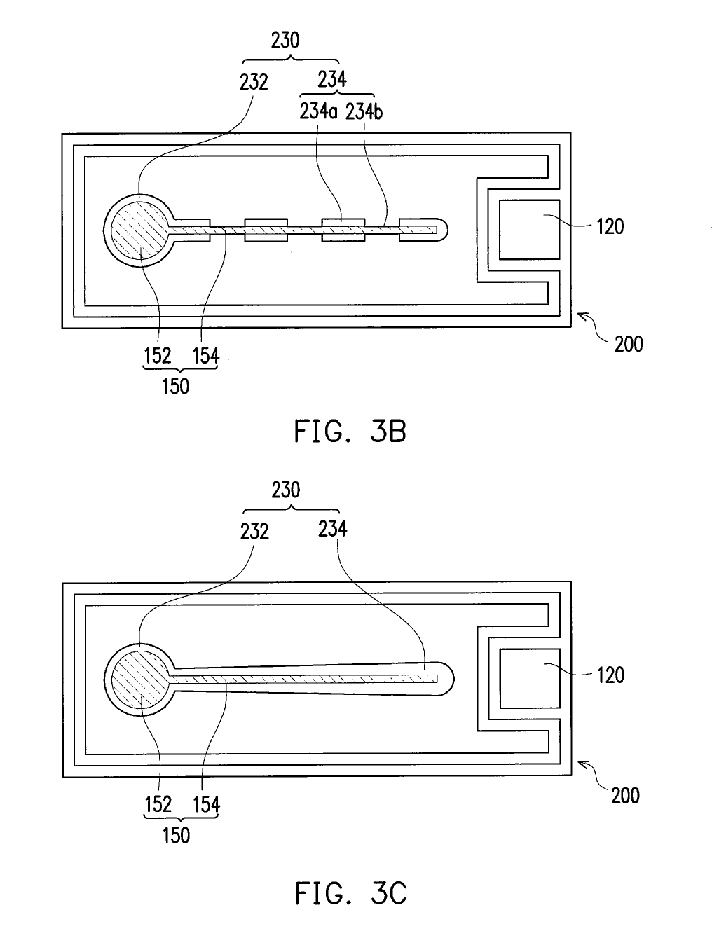

FIG. 3A to FIG. 3C are top views of different light-emitting diode chips according to the second embodiment of the invention. Referring to FIG. 1A to FIG. 1C and FIG. 3A, a light-emitting diode chip 200 of the present embodiment includes a semiconductor device layer 110, a first electrode 120, a current-blocking layer 230, a current-spreading layer 140, and a second electrode 150. The semiconductor device layer 110 includes a first-type doped semiconductor layer 112, a light-emitting layer 114, and a second-type doped semiconductor layer 116, wherein the light-emitting layer 114 is located between the first-type doped semiconductor layer 112 and the second-type doped semiconductor layer 116. The first electrode 120 is electrically connected to the first-type doped semiconductor layer 112. The current-blocking layer 230 includes a main body 232 and an extending portion 234 extended from the main body 232. The current-blocking layer 230 is disposed on the second-type doped semiconductor layer 116. The current-spreading layer 140 is disposed on the second-type doped semiconductor layer 116 to cover the current-blocking layer 230. The second electrode 10 is electrically connected to the second-type doped semiconductor layer 116 via the current-spreading layer 140, wherein the second electrode 150 includes a bond pad 152 and a finger portion 154 extended from the bond pad 152, the bond pad 152 is located above the main body 132, the finger portion 154 is located above the extending portion 134, and the extending portion 234 has a plurality of widths along the extending direction of the finger portion 154.

Since the extending portion 234 has a plurality of widths along the extending direction of the finger portion 154, the extending portion 234 can be divided into a plurality of portions having different widths. Specifically, the portion in the extending portion 234 having a greater width has greater blocking power against the driving current from the second electrode 150, and the portion in the extending portion 234 having a smaller width has smaller blocking power against the driving current from the second electrode 150. In the present embodiment, the locations of the current-collecting regions in the light-emitting diode chip 200 can be controlled via the extending portion 234 having a plurality of widths to improve the luminous efficiency of the light-emitting diode chip 200.

In the present embodiment, the light-emitting layer 114 is disposed on the first-type doped semiconductor layer 112 to expose a portion of the first-type doped semiconductor layer 112, and the first electrode 120 is disposed on the portion of the first-type doped semiconductor layer 112 exposed by the light-emitting layer 114. In other words, the light-emitting diode chip 200 of the present embodiment is a horizontal-type light-emitting diode chip. For instance, the first-type doped semiconductor layer 112 in the semiconductor device layer 110 is, for instance, an N-type doped semiconductor layer, the second-type doped semiconductor layer 116 is, for instance, a P-type doped semiconductor layer, and the light-emitting layer 114 is, for instance, a multiple quantum well (MQW) formed by a plurality of alternately-stacked well layers and barrier layers. Moreover, the semiconductor device layer 110 of the present embodiment is, for instance, manufactured on a substrate SUB via an epitaxial process, and the substrate SUB can be, for instance, a sapphire substrate, a silicon substrate, or a silicon carbide substrate.

It should be mentioned that, the above semiconductor device layer 110 can further include a buffer layer 160, and the buffer layer 160 is generally formed on the substrate SUB before the manufacture of the first-type doped semiconductor layer 112. In other words, the buffer layer 160 can be optionally formed between the substrate SUB and the semiconductor device layer 110 to provide suitable stress relief and improve the epitaxial quality of a subsequently-formed thin film.

In the present embodiment, the first electrode 120 is, for instance, a metal material having good Ohmic contact with the first-type doped semiconductor layer 112, the material of the current-blocking layer 230 is, for instance, a dielectric layer, the material of the current-spreading layer 140 is, for instance, a transparent conducting material, and the second electrode 150 is, for instance, a metal material having good Ohmic contact with the current-spreading layer 140. For instance, the material of the first electrode 120 includes a conducting material such as chromium (Cr), gold (Au), aluminum (Al), or titanium (Ti), the material of the current-blocking layer 230 includes a dielectric material such as silicon oxide (SiOx) or silicon nitride (SiNx), the material of the current-spreading layer 140 includes a transparent conducting material such as indium-tin-oxide (ITO) or indium-zinc-oxide (IZO), and the material of the second electrode 150 includes a conducting material such as Cr, Au, Al, or Ti.

The current-blocking layer 230 of the present embodiment can adopt different designs, and in the following, different designs of the current-blocking layer 230 are described with reference to FIG. 3A to FIG. 3C.

As shown in FIG. 3A and FIG. 3B, the widths of the extending portion 234 of the present embodiment can vary periodically along the extending direction of the finger portion 154. More specifically, the extending portion 234 has two or more widths, and the width of the extending portion 234 at any location is greater than the width of the finger portion 154 (as shown in FIG. 3A), or the width of the extending portion 234 at a partial region is equal to the width of the finger portion 154, and the widths at other regions are greater than the width of the finger portion 154 (as shown in FIG. 3B). For instance, the extending portion 234 of the present embodiment includes a plurality of current-blocking patterns 234a and a plurality of connecting patterns 234b arranged along the extending direction of the finger portion 154, wherein the current-blocking patterns 234a are connected to one another via the connecting patterns 234b. Moreover, the connecting patterns 234b are overlapped with the finger portion 154, and the width of each of the connecting patterns 234b along the extending direction of the finger portion 154 is greater than the width of the finger portion 154 (as shown in FIG. 3A), or the width of each of the connecting patterns 234b is equal to the width of the finger portion 154 (as shown in FIG. 3B). As shown in FIG. 3C, in the current-blocking layer 230 of the present embodiment, the widths of the extending portion 234 are gradually changed along the extending direction of the finger portion 154, and the widths of the extending portion 234 are greater closer to the first electrode 120.

### Third Embodiment

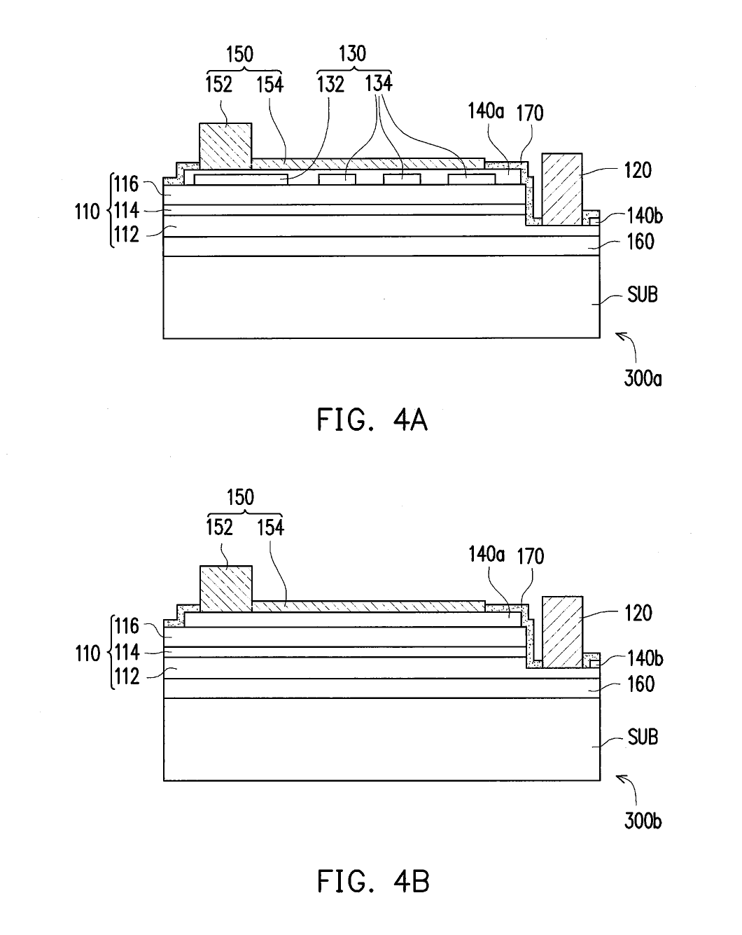

FIG. 4A to FIG. 4B are cross-sectional views of different light-emitting diode chips according to the third embodiment of the invention. Please refer to FIG. 4A first. In the present embodiment, a light-emitting diode chip 300a is similar to the light-emitting diode chip 100a of the embodiment of FIG. 1A. The components of the light-emitting diode chip 300a and relating description are as provided for the light-emitting diode chip 100a of the embodiment of FIG. 1A and are not repeated herein. The difference between the light-emitting diode chip 300a and the light-emitting diode chip 100a is that the light-emitting diode chip 300a includes a current-spreading layer 140a and a current-spreading layer 140b. The current-spreading layer 140a is disposed on the second-type doped semiconductor layer 116 to cover the current-blocking layer 130, and the current-spreading layer 140b is disposed on the first-type doped semiconductor layer 112. In the present embodiment, the light-emitting diode chip 300a further includes a protective layer 170 disposed on the semiconductor device layer 110. The current-spreading layer 140a and the current-spreading layer 140b are disposed between the protective layer 170 and the semiconductor device layer 110. Specifically, the protective layer 170 is disposed on the current-spreading layer 140a and the current-spreading layer 140b, and the material of the protective layer 170 can also be a light-permeable film layer such as silicon oxide. The index of refraction of the protective layer 170 material is, for instance, between 1.4 and 1.6.

In the present embodiment, the materials of the current-spreading layer 140a and the current-spreading layer 140b include a transparent conducting material. Moreover, the index of refraction of the current-spreading layer 140a is between the indexes of refraction of the protective layer 170 and the second-type doped semiconductor layer 116, and the index of refraction of the current-spreading layer 140b is between the indexes of refraction of the protective layer 170 and the first-type doped semiconductor layer 112. For instance, the index of refraction of the current-spreading layer 140b (or the current-spreading layer 140a) is, for instance, 1.9, the index of refraction of the protective layer 170 is, for instance, between 1.4 and 1.6, and the index of refraction of the first-type doped semiconductor layer 112 (or the second-type doped semiconductor layer 116) is, for instance, 2.3. Specifically, since in the present embodiment, the index of refraction of the stacked first-type doped semiconductor layer 112, current-spreading layer 140b, and protective layer 170 is gradually changed, the current-spreading layer 140b eliminates the difference in index of refraction between the protective layer 170 and the first-type doped semiconductor layer 112. When light passes through the first-type doped semiconductor layer 112, the current-spreading layer 140b, and the protective layer 170 in order, since the difference in index of refraction between the stacked structure is less, the light emitted by the light-emitting layer 114 has a greater total reflection angle, such that total reflection occurs less readily thereto and the refraction ratio is increased as a result. Therefore, the optical efficiency of the light-emitting diode chip 300a is increased. In the present embodiment, the materials of the current-spreading layer 140a and the current-spreading layer 140b are ITO. However, in some embodiments, the materials of the current-spreading layer 140a and the current-spreading layer 140b can also be ITO, nickel (Ni), Au, Cr, Ti, Al, or a combination thereof, and the invention is not limited thereto.

In the present embodiment, similar to the light-emitting diode chip 100a of the embodiment of FIG. 1A, the locations of the current-collecting regions in the light-emitting diode chip 300a can be controlled via the pattern designs of the extending portion 134 and the finger portion 154 and the overlapping condition of the two, so as to improve the luminous efficiency of the light-emitting diode chip 300a.

Next, please refer to FIG. 4B. In the present embodiment, a light-emitting diode chip 300b is similar to the light-emitting diode chip 300a of the embodiment of FIG. 4A. The components of the light-emitting diode chip 300b and relating description are as provided for the light-emitting diode chip 300a of the embodiment of FIG. 4A and are not repeated herein. The difference between the light-emitting diode chip 300b and the light-emitting diode chip 300a is that the light-emitting diode chip 300b does not include a current-blocking layer. Moreover, in the present embodiment, the index of refraction of the current-spreading layer 140a is between the indexes of refraction of the protective layer 170 and the second-type doped semiconductor layer 116, and the index of refraction of the current-spreading layer 140b is between the indexes of refraction of the protective layer 170 and the first-type doped semiconductor layer 112. Therefore, similar to the light-emitting diode chip 300a of the embodiment of FIG. 4A, total reflection occurs less readily to the light emitted by the light-emitting layer 114 of the light-emitting diode chip 300b, such that the optical efficiency of the light-emitting diode chip 300b is increased.

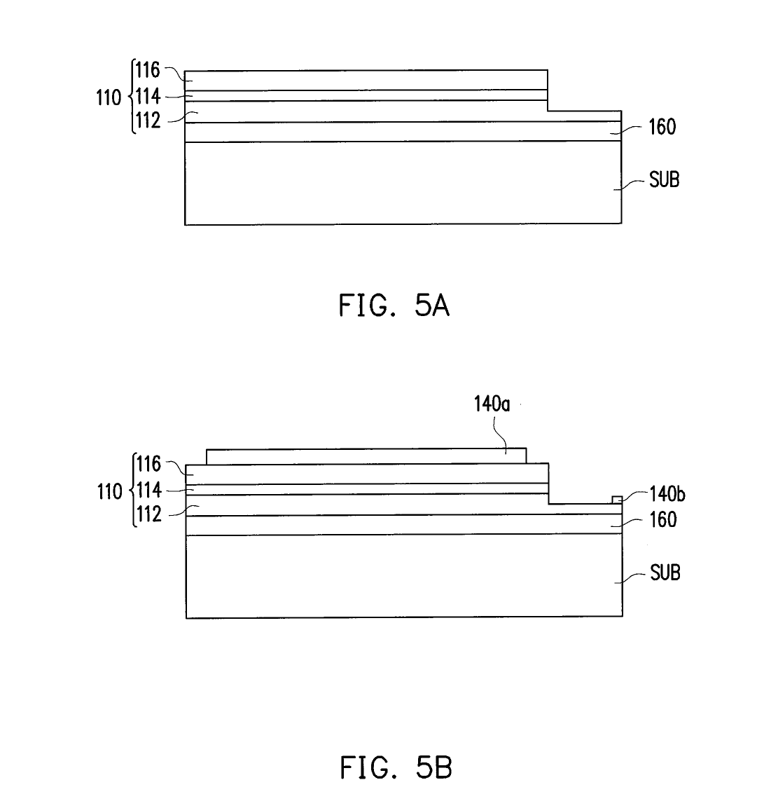

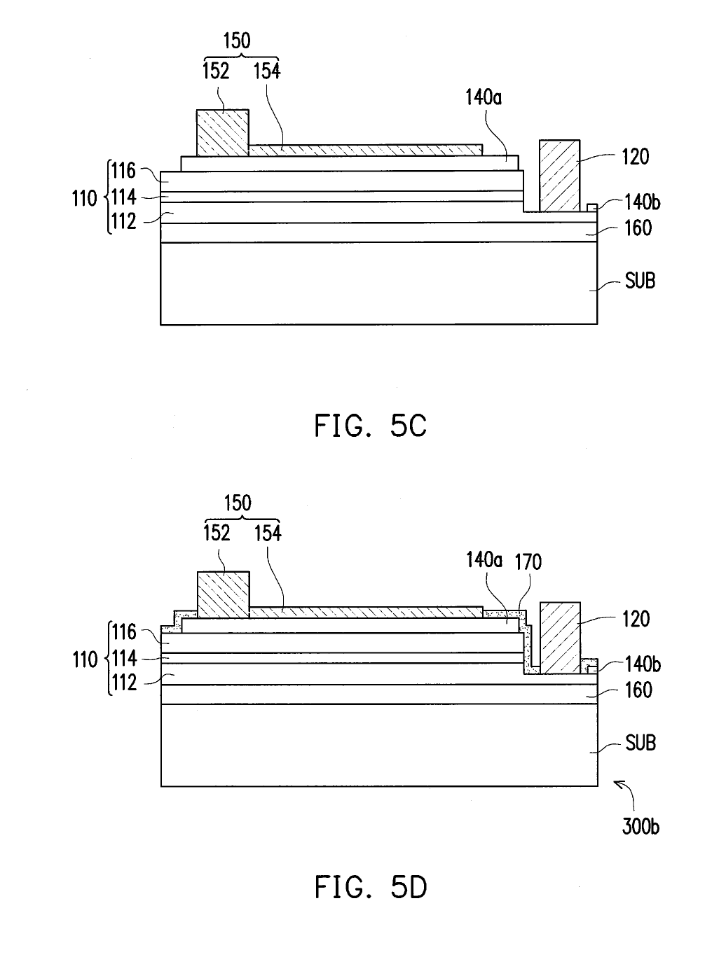

FIG. 5A to FIG. 5D are flowcharts of the manufacturing method of the light-emitting diode chip of the embodiment of FIG. 4B. Please refer to FIG. 5A first. In the present embodiment, the manufacturing method of the light-emitting diode chip 300a of the embodiment of FIG. 4A includes growing the semiconductor device layer 110 on the substrate SUB. The semiconductor device layer 110 has the first-type doped semiconductor layer 112, the light-emitting layer 114, and the second-type doped semiconductor layer 116. Specifically, the first-type doped semiconductor layer 112 is formed on the substrate SUB, the light-emitting layer 114 is formed on the first-type doped semiconductor layer 112, and the second-type doped semiconductor layer 116 is formed on the light-emitting layer 114. Moreover, in the present embodiment, before the manufacture of the first-type doped semiconductor layer 112, the buffer layer 160 is first formed on the substrate SUB.

Next, please refer to FIG. 5A and FIG. 5B. In the present embodiment, the light-emitting layer 114 is disposed on the first-type doped semiconductor layer 112 to expose a portion of the first-type doped semiconductor layer 112. Specifically, the first-type doped semiconductor layer 112, the light-emitting layer 114, and the second-type doped semiconductor layer 116 are, for instance, formed by epitaxy. Moreover, a portion of the first-type doped semiconductor layer 112, the light-emitting layer 114, and the second-type doped semiconductor layer 116 are removed via etching to expose a portion of the first-type doped semiconductor layer 112. In the present embodiment, the manufacturing method of the light-emitting diode chip 300a includes forming a current-spreading layer 140a on the second-type doped semiconductor layer 116 and on a portion of the first-type doped semiconductor layer 112 exposed by the current-spreading layer 140b on the light-emitting layer 114. Specifically, the current-spreading layer 140a and the current-spreading layer 140b can further expose the first-type doped semiconductor layer 112 and the second-type doped semiconductor layer 116 by etching and keeping a partial region so as to provide space for disposing a subsequent electrode and to prevent a short circuit caused by the connection between the current-spreading layer 140a and the current-spreading layer 140b at the same time.

Referring to FIG. 5C, in the present embodiment, the manufacturing method of the light-emitting diode chip 300a includes forming the first electrode 120 and the second electrode 150 such that the first electrode 120 and the second electrode 150 are respectively electrically connected to the first-type doped semiconductor layer 112 and the current-spreading layer 140a. Specifically, the first electrode 120 is disposed on the portion of the first-type doped semiconductor layer 112 exposed by the light-emitting layer 114.

Then, referring to FIG. 5D, in the present embodiment, the manufacturing method of the light-emitting diode chip 300a includes forming the protective layer 170 on the surface of the semiconductor device layer 110 and covering a portion of the current-spreading layer 140a and a portion of the current-spreading layer 140b. Specifically, the index of refraction of the current-spreading layer 140a is between the indexes of refraction of the protective layer 170 and the second-type doped semiconductor layer 116, and the index of refraction of the current-spreading layer 140b is between the indexes of refraction of the protective layer 170 and the first-type doped semiconductor layer 112.

### Fourth Embodiment

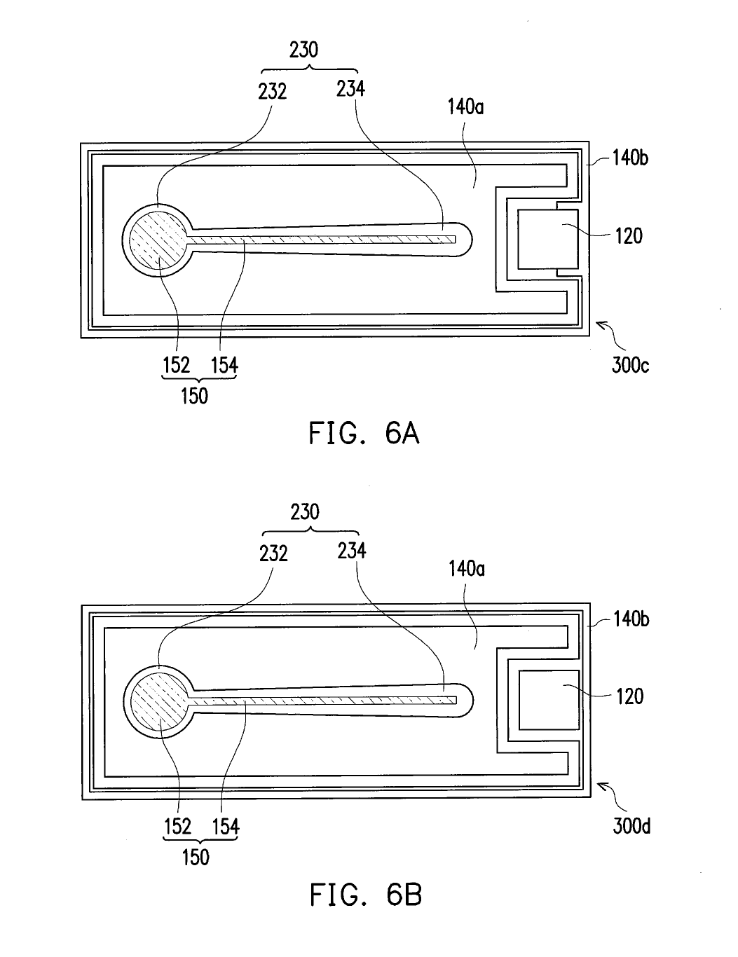

FIG. 6A to FIG. 6B are top views of different light-emitting diode chips according to the fourth embodiment of the invention. Please refer to FIG. 6A and FIG. 6B. In the present embodiment, a light-emitting diode chip 300c of FIG. 6A and a light-emitting diode chip 300d of FIG. 6B are similar to the light-emitting diode chip 200 of the embodiment of FIG. 3C. The components of the light-emitting diode chip 300c and relating description and the components of the light-emitting diode chip 300d and relating description are as provided for the light-emitting diode chip 200 of the embodiment of FIG. 3C and are not repeated herein. In the present embodiment, the difference between the light-emitting diode chip 300c of FIG. 6A and the light-emitting diode chip 300d of FIG. 6B is that the current-spreading layer 140b of the light-emitting diode chip 300c is in contact with a side of the first electrode 120, and the current-spreading layer 140b of the light-emitting diode chip 300d is not in contact with the side of the first electrode 120. Specifically, the current-spreading layer 140b can be controlled to be in contact or not be in contact with the side of the first electrode 120 by changing the technical means of the photomask in the process, and the invention is not limited thereto. Moreover, the current-spreading layer 140a and the current-spreading layer 140b of an embodiment of the invention have a low effect on electrical property. Therefore, the current-spreading layer 140a and the current-spreading layer 140b can reduce variation in the index of refraction on the light-exit path of the light without affecting the electrical performance of the light-emitting diode chip to improve the optical efficiency of the light-emitting diode chip.

### Fifth Embodiment

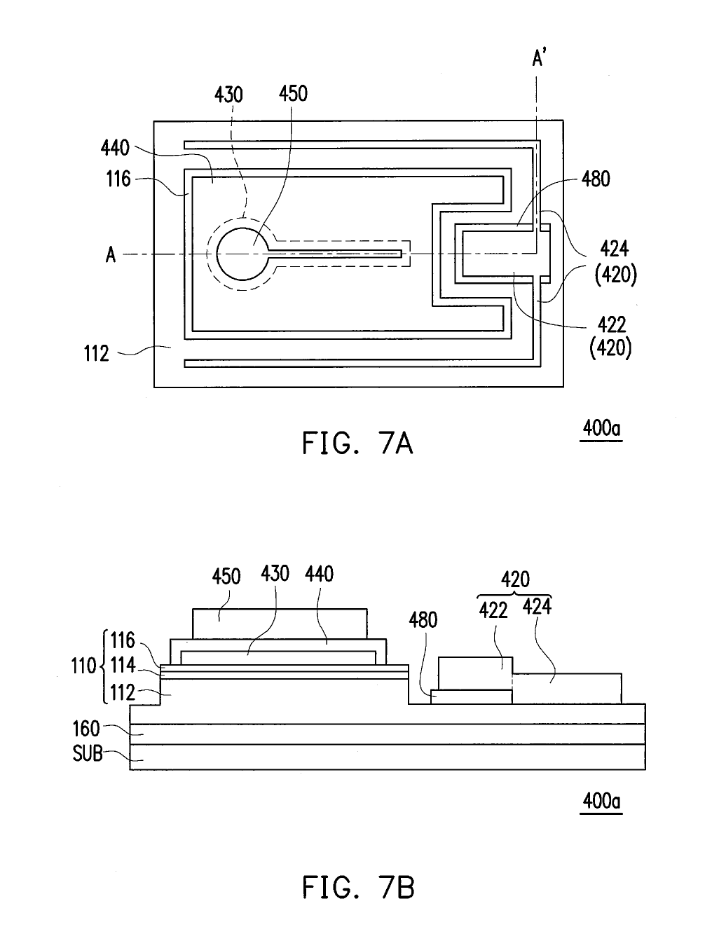

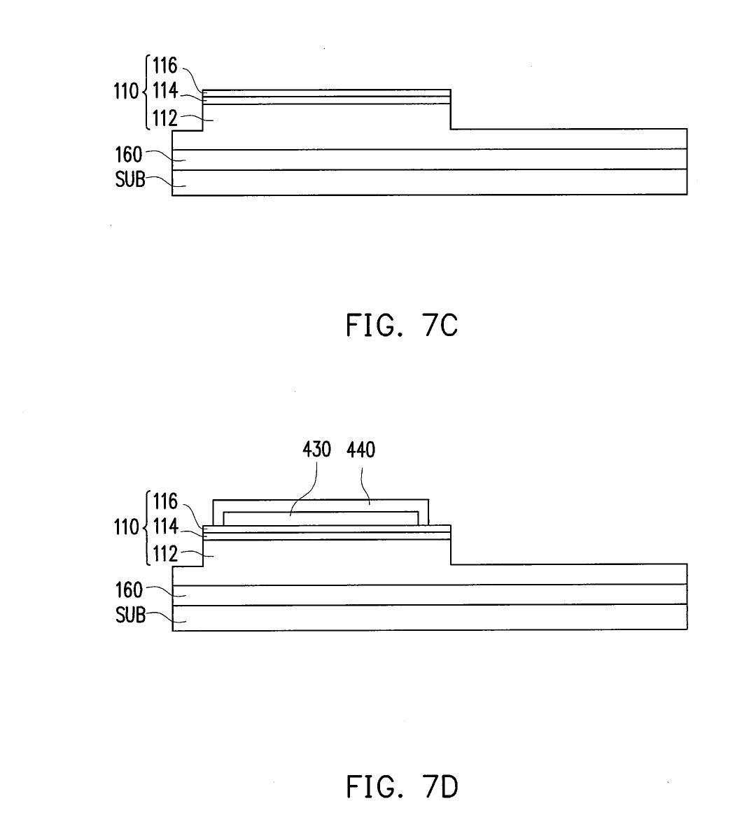

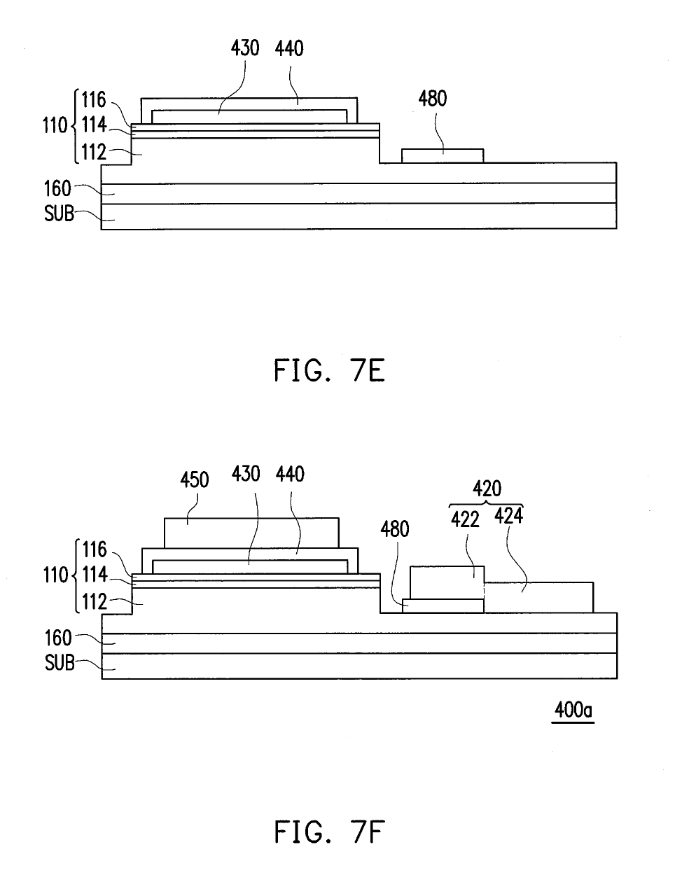

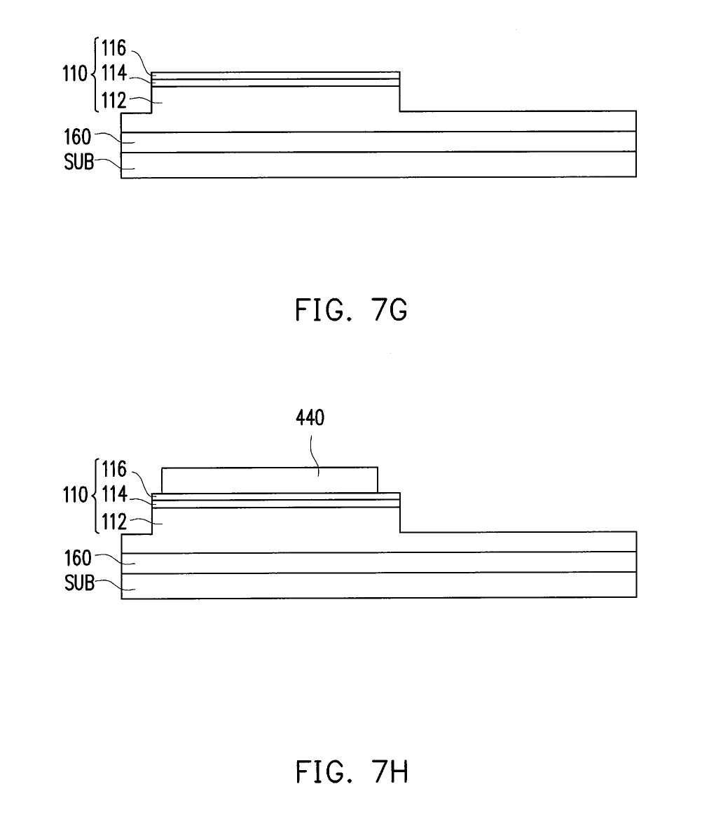

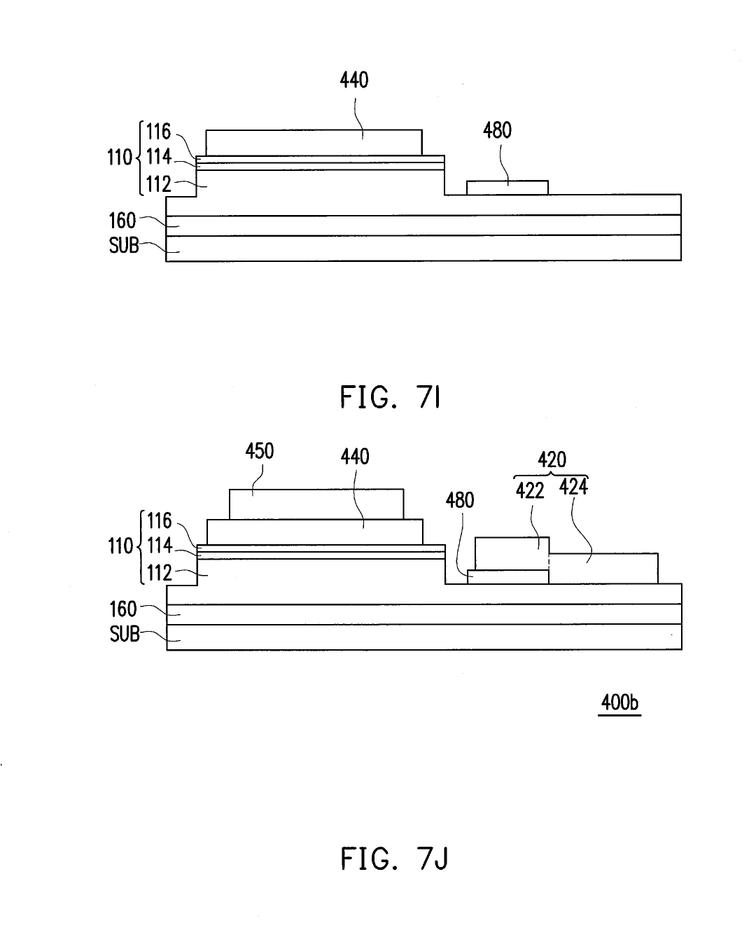

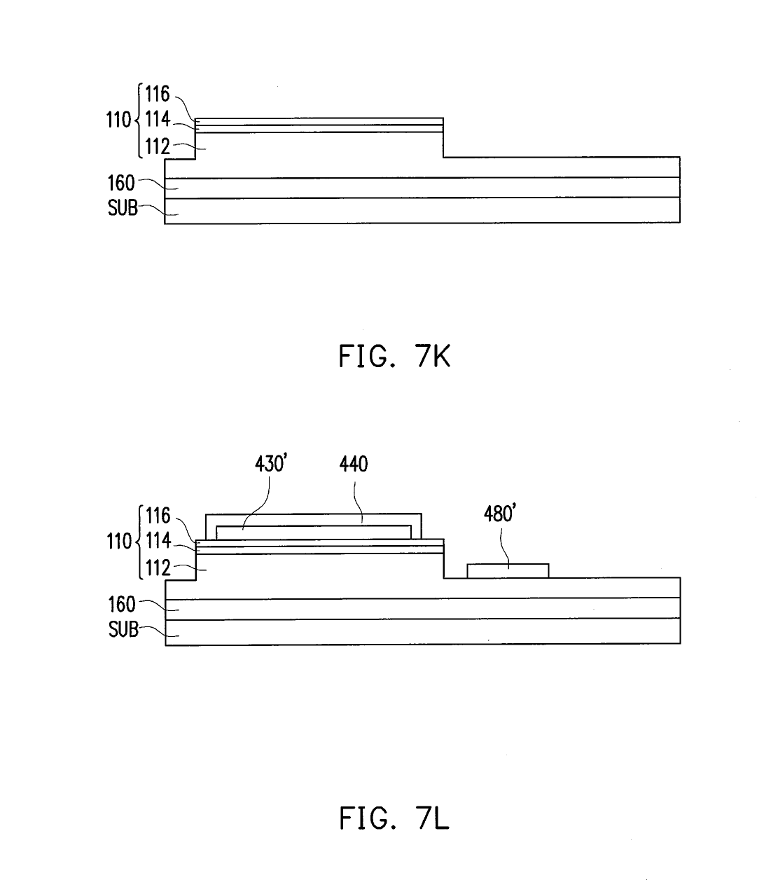

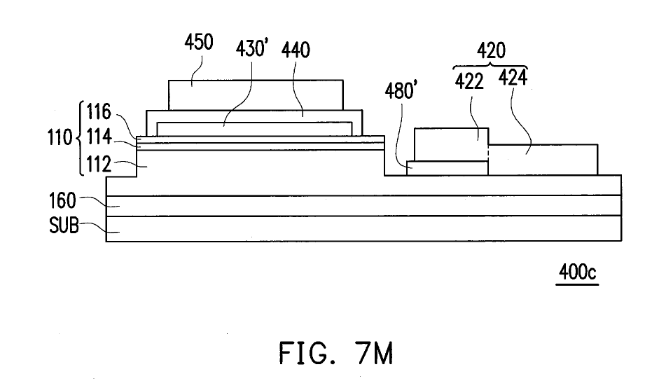

FIG. 7A is a top view of the light-emitting diode chip according to the fifth embodiment of the invention, and FIG. 7B is a cross-sectional view of the light-emitting diode chip of FIG. 7A along line A-A′. In the present embodiment, a light-emitting diode chip 400a is similar to the light-emitting diode chip 100a of FIG. 1A. Specifically, the light-emitting diode chip 400a includes a semiconductor device layer 110, a current-spreading layer 440, a first electrode 420, an insulating layer 480, and a second electrode 450. The semiconductor device layer 110 includes the first-type doped semiconductor layer 112, the light-emitting layer 114, and the second-type doped semiconductor layer 116. The light-emitting layer 114 is located between the first-type doped semiconductor layer 112 and the second-type doped semiconductor layer 116. In the present embodiment, the current-spreading layer 440 is disposed on the second-type doped semiconductor layer 116. The first electrode 420 is electrically connected to the first-type doped semiconductor layer 112, and the insulating layer 480 is disposed between the first electrode 420 and the first-type doped semiconductor layer 112. Moreover, the second electrode 450 is electrically connected to the second-type doped semiconductor layer 116 via the current-spreading layer 440. Specifically, the light-emitting diode chip 400a further includes a current-blocking layer 430 disposed between the current-spreading layer 440 and the second-type doped semiconductor layer 116. The current-blocking layer 430 can be, for instance, the current-blocking layer 130 of the light-emitting diode chip 100a of the embodiment of FIG. 1A, and can also be other types of current-blocking layer, and the invention is not limited thereto. Moreover, the components and the disposition of the components of the light-emitting diode chip 400a and relating description are as provided for the light-emitting diode chip 100a of FIG. 1A and are not repeated herein.

In the present embodiment, the first electrode 420 includes a bond portion 422 and branched portions 424 extended from the bond portion 422. Specifically, the bond portion 422 is disposed above the insulating layer 480. The insulating layer 480 is configured to block electrons from circulating to the first-type doped semiconductor layer 112 from the bond portion 422 of the first electrode 420, such that the electrons are circulated from the bond portion 422 of the first electrode 420 to the branched portions 424 and the electrons are circulated to the first-type doped semiconductor layer 112 via the branched portions 424. In the present embodiment, since the branched portions 424 are extended from the bond portion 422 to a location farther than the bond portion 422, the electrons provided by driving the light-emitting diode chip 400a externally are circulated from the bond portion 422 to the branched portions 424, and are spread to a location farther than the bond portion 422 via the branched portions 424, such that the electrons can reach the portion of the first-type doped semiconductor layer 112 corresponding to the location farther than the bond portion 422. Specifically, the electrons provided by driving the light-emitting diode chip 400a externally reach the corresponding location of the first-type doped semiconductor layer 112 via the branched portions 424 distributed on the first-type doped semiconductor layer 112. Therefore, the region of the first-type doped semiconductor layer 112 receiving the electrons at least includes a region of the branched portions 424 in contact with the first-type doped semiconductor layer 112, such that the combination probability of the electrons provided by the first electrode 420 and the electron holes provided by the second electrode 450 is increased and more photons are generated as a result. Therefore, the luminous efficiency of the light-emitting diode chip 400a is increased.

In the present embodiment, the material of the insulating layer 480 is, for instance, a dielectric layer. For instance, the material of the insulating layer 480 includes a dielectric material such as SiOₓ or SiNₓ. In some embodiments, the material of the insulating layer 480 can also be other types of dielectric material, and the material of the insulating layer 480 can be the same or different than the material of the current-blocking layer 430, and the invention is not limited thereto. Moreover, in the present embodiment, the light-emitting diode chip 400a can include the protective layer 170 of the light-emitting diode chip 300a of the embodiment of FIG. 4A and FIG. 4B, and the invention is also not limited thereto.

### Sixth Embodiment

FIG. 7C to FIG. 7F, FIG. 7G to FIG. 7J, and FIG. 7K to FIG. 7M are flowcharts of the manufacturing method of different light-emitting diode chips according to the sixth embodiment of the invention. Please refer first to FIG. 7C to FIG. 7F, and refer to FIG. 5A to FIG. 5D at the same time. In the present embodiment, the structure of the light-emitting diode chip 400a is the same as the light-emitting diode chip 400a of the embodiment of FIG. 7A and FIG. 7B. The manufacturing method of the light-emitting diode chip 400a of the present embodiment is similar to the manufacturing method of the light-emitting diode chip 300a of the embodiment of FIG. 5A to FIG. 5D. Specifically, referring first to FIG. 7C, the manufacturing method of the light-emitting diode chip 400a of the present embodiment includes growing the semiconductor device layer 110 on the substrate SUB. The semiconductor device layer 110 has the first-type doped semiconductor layer 112, the light-emitting layer 114, and the second-type doped semiconductor layer 116. The first-type doped semiconductor layer 112 is formed on the substrate SUB, the light-emitting layer 114 is formed on the first-type doped semiconductor layer 112, and the second-type doped semiconductor layer 116 is formed on the light-emitting layer 114. Moreover, in the present embodiment, before the manufacture of the first-type doped semiconductor layer 112, the buffer layer 160 is first formed on the substrate SUB. Moreover, the light-emitting layer 114 is disposed on the first-type doped semiconductor layer 112 to expose a portion of the first-type doped semiconductor layer 112. Then, referring to FIG. 7D, the current-blocking layer 430 and the current-spreading layer 440 are formed on the second-type doped semiconductor layer 116, and the current-blocking layer 430 is located between the current-spreading layer 440 and the second-type doped semiconductor layer 116.

Then, please refer to FIG. 7E. In the present embodiment, the manufacturing method of the light-emitting diode chip 400a includes forming the insulating layer 480 on the portion of the first-type doped semiconductor layer 112 exposed by the light-emitting layer 114. Then, referring to FIG. 7F, the first electrode 420 and the second electrode 450 are formed such that the first electrode 420 and the second electrode 450 are respectively electrically connected to the first-type doped semiconductor layer 112 and the current-spreading layer 440 to form the light-emitting diode chip 400a. Specifically, the first electrode 420 of the light-emitting diode chip 400a includes the bond portion 422 and the branched portions 424 extended from the bond portion 422, and the bond portion 422 is disposed above the insulating layer 480.

FIG. 7G to FIG. 7J are flowcharts of the manufacturing method of the other light-emitting diode chips of the sixth embodiment of the invention. Please refer to FIG. 7G to FIG. 7J, and at the same time refer to FIG. 7C to FIG. 7F. A light-emitting diode chip 400b is similar to the light-emitting diode chip 400a of FIG. 7C to FIG. 7F, and the manufacturing method of the light-emitting diode chip 400b of the present embodiment is similar to the manufacturing method of the light-emitting diode chip 400a of the embodiment of FIG. 7C to FIG. 7F. In the present embodiment, referring first to FIG. 7G, the manufacturing method of the light-emitting diode chip 400b of the present embodiment includes growing the semiconductor device layer 110 on the substrate SUB. Moreover, referring to FIG. 7H, the current-spreading layer 440 is formed on the second-type doped semiconductor layer 116. Specifically, in the manufacturing method of the light-emitting diode chip 400b, a current-blocking layer is not formed on the second-type doped semiconductor layer 116. Then, referring to FIG. 7I, the insulating layer 480 is formed on the portion of the first-type doped semiconductor layer 112 exposed by the light-emitting layer 114. Then, referring to FIG. 7J, the first electrode 420 and the second electrode 450 are formed such that the first electrode 420 and the second electrode 450 are respectively electrically connected to the first-type doped semiconductor layer 112 and the current-spreading layer 440 to form the light-emitting diode chip 400b.

FIG. 7K to FIG. 7M are flowcharts of the manufacturing method of the other light-emitting diode chips of the sixth embodiment of the invention. Please refer to FIG. 7K to FIG. 7M, and at the same time refer to FIG. 7C to FIG. 7F. A light-emitting diode chip 400c is similar to the light-emitting diode chip 400a of FIG. 7C to FIG. 7F, and the manufacturing method of the light-emitting diode chip 400c of the present embodiment is similar to the manufacturing method of the light-emitting diode chip 400a of the embodiment of FIG. 7C to FIG. 7F. In the present embodiment, referring first to FIG. 7K, the manufacturing method of the light-emitting diode chip 400c of the present embodiment includes growing the semiconductor device layer 110 on the substrate SUB. Moreover, referring to FIG. 7L, a current-blocking layer 430′ is formed on the second-type doped semiconductor layer 116, and an insulating layer 480′ is formed on the portion of the first-type doped semiconductor layer 112 exposed by the light-emitting layer 114 at the same time. Specifically, the materials of the current-blocking layer 430′ and the insulating layer 480′ can be the same or different. Moreover, the current-spreading layer 440 is formed on the second-type doped semiconductor layer 116 such that the current-blocking layer 430′ is located between the current-spreading layer 440 and the second-type doped semiconductor layer 116. Then, referring to FIG. 7M, the first electrode 420 and the second electrode 450 are formed such that the first electrode 420 and the second electrode 450 are respectively electrically connected to the first-type doped semiconductor layer 112 and the current-spreading layer 440 to form the light-emitting diode chip 400c.

### Seventh Embodiment

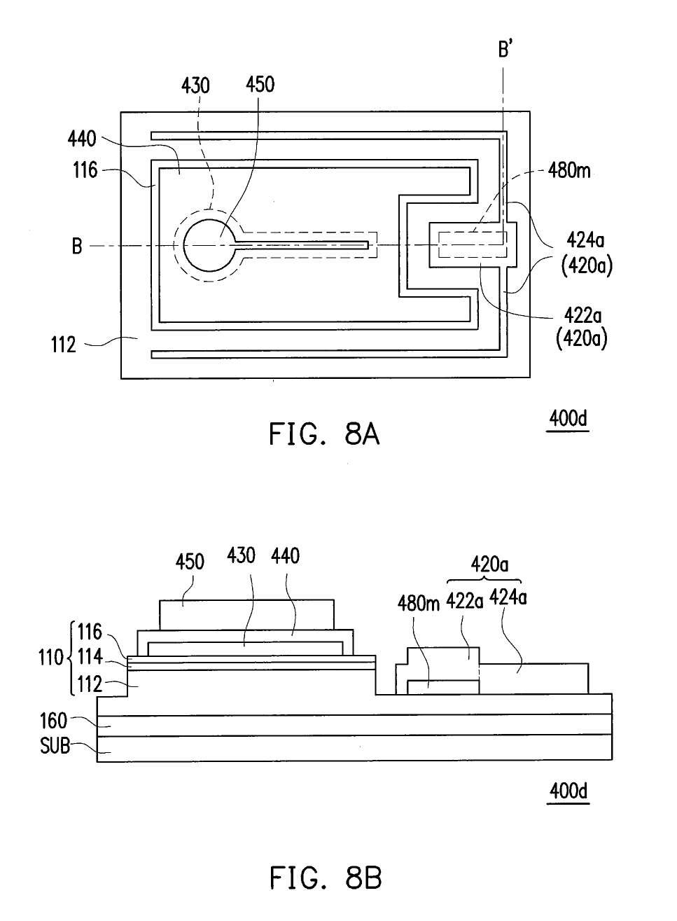

FIG. 8A is a top view of the light-emitting diode chip according to the seventh embodiment of the invention, and FIG. 8B is a cross-sectional view of the light-emitting diode chip of FIG. 8A along line B-B′. Please refer to FIG. 8A and FIG. 8B. In the present embodiment, a light-emitting diode chip 400d is the same as the light-emitting diode chip 400a of the embodiment of FIG. 7A and FIG. 7B. The components of the light-emitting diode chip 400d and relating description are as provided for the light-emitting diode chip 400a of FIG. 7A and FIG. 7B and are not repeated herein. The difference between the light-emitting diode chip 400d and the light-emitting diode chip 400a is that, a first electrode 420a of the light-emitting diode chip 400d includes a bond portion 422a and branched portions 424a extended from the bond portion 422a. Specifically, the bond portion 422a is disposed above an insulating layer 480a, and the bond portion 422a covers the insulating layer 480a. In the present embodiment, the insulating layer 480a is disposed between the first electrode 420a and the first-type doped semiconductor layer 112, and the first electrode 420a includes the branched portions 424a extended from the bond portion 422a. Therefore, in the light-emitting diode chip 400d, the combination probability of the electrons provided by the first electrode 420a and the electron holes provided by the second electrode 450 is increased to generate more photons, such that the light-emitting diode chip 400d has a similar effect of increasing luminous efficiency to the light-emitting diode chip 400a of the embodiment of FIG. 7A and FIG. 7B.

### Eighth Embodiment

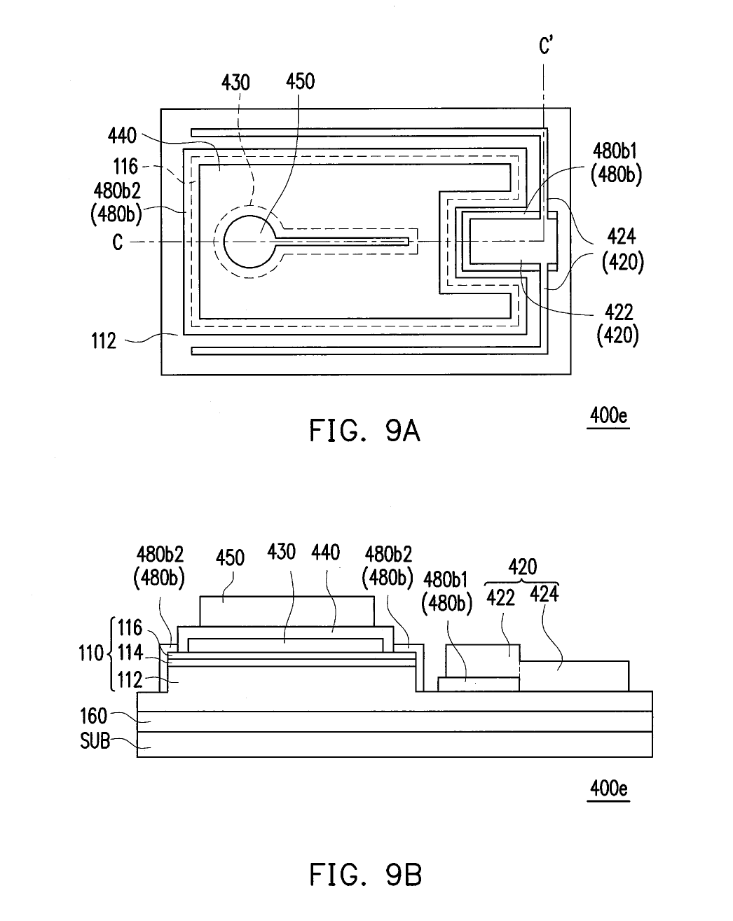

FIG. 9A is a top view of the light-emitting diode chip according to the eighth embodiment of the invention, and FIG. 9B is a cross-sectional view of the light-emitting diode chip of FIG. 9A along line C-C′. Please refer to FIG. 9A and FIG. 9B. In the present embodiment, a light-emitting diode chip 400e is similar to the light-emitting diode chip 400a of the embodiment of FIG. 7A and FIG. 7B. The components of the light-emitting diode chip 400e and relating description are as provided for the light-emitting diode chip 400a of FIG. 7A and FIG. 7B and are not repeated herein. The difference between the light-emitting diode chip 400e and the light-emitting diode chip 400a is that, an insulating layer 480b of the light-emitting diode chip 400e includes an insulating layer 480b1 and an insulating layer 480b2. In the present embodiment, the insulating layer 480b1 is disposed between the first electrode 420 and the first-type doped semiconductor layer 112, and the insulating layer 480b2 is disposed on the second-type doped semiconductor layer 116. Specifically, the insulating layer 480b2 covers the second-type doped semiconductor layer 116, the light-emitting layer 114, and the exposed portion of first-type doped semiconductor layer 112. Moreover, in the present embodiment, the insulating layer 480b1 (insulating layer 480b), the insulating layer 480b2 (insulating layer 480b), and the current-blocking layer 430 can adopt the same or different material, and the invention is not limited thereto. In the present embodiment, the insulating layer 480b1 is disposed between the first electrode 420 and the first-type doped semiconductor layer 112, and the first electrode 420 includes the branched portions 424 extended from the bond portion 422. Therefore, the light-emitting diode chip 400e has a similar effect of increasing luminous efficiency to the light-emitting diode chip 400a of the embodiment of FIG. 7A and FIG. 7B.

### Ninth Embodiment

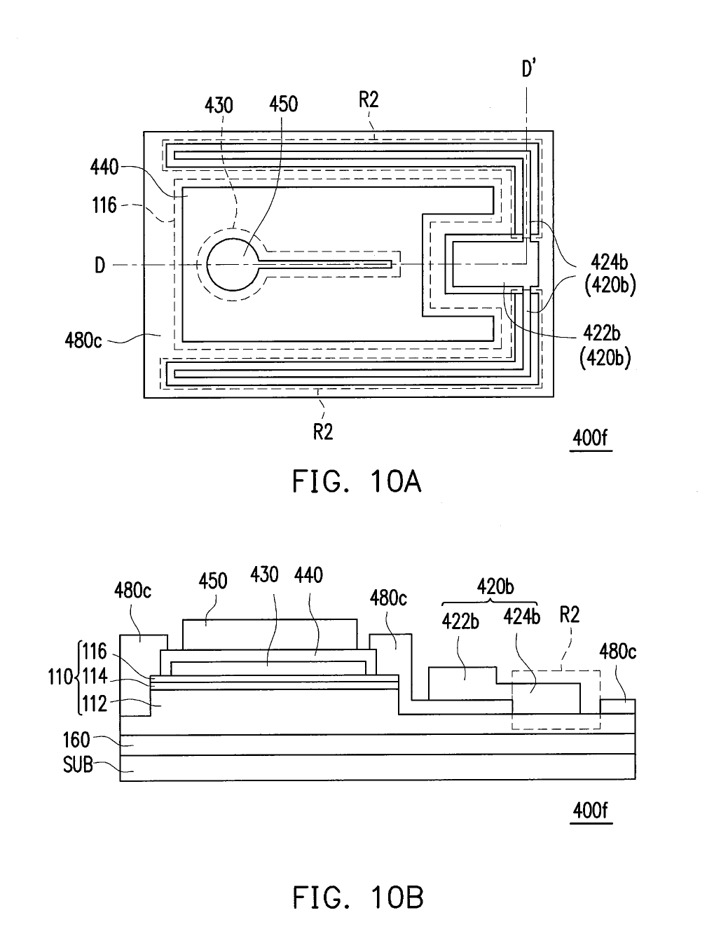

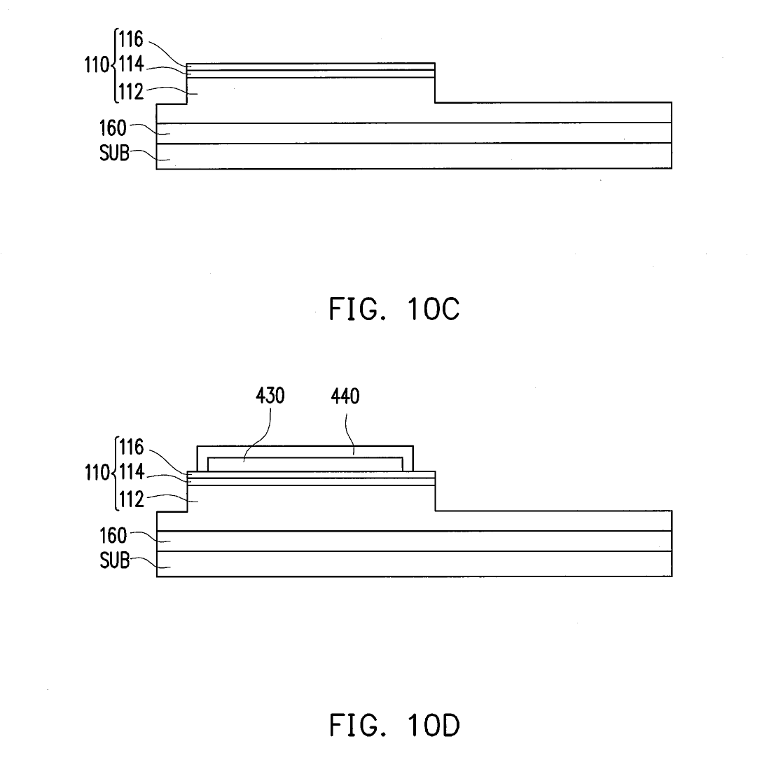

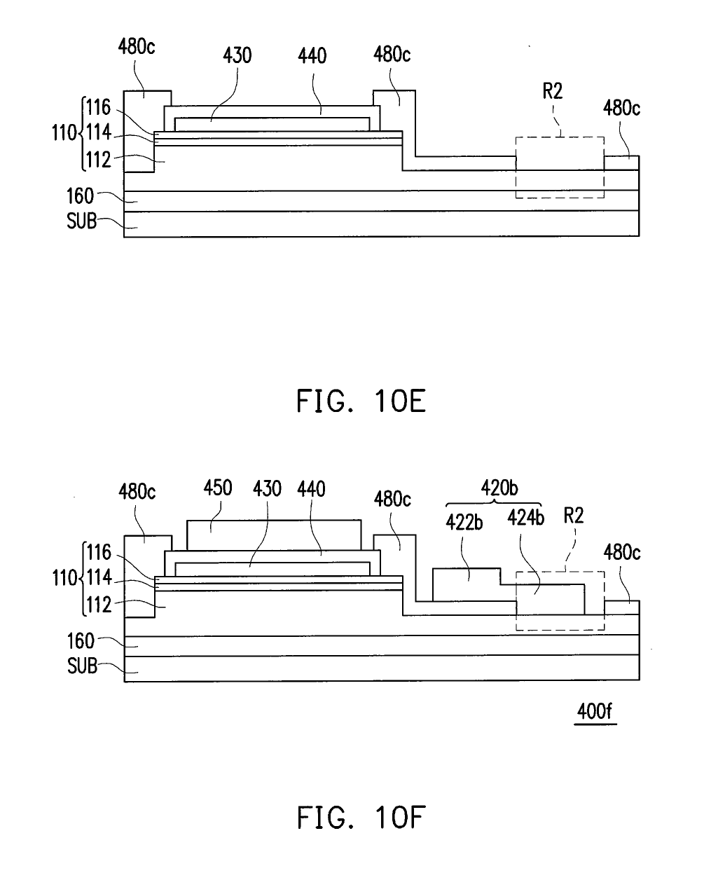

FIG. 10A is a top view of the light-emitting diode chip according to the ninth embodiment of the invention, and FIG. 10B is a cross-sectional view of the light-emitting diode chip of FIG. 10A along line D-D′. Please refer to FIG. 10A and FIG. 10B. In the present embodiment, a light-emitting diode chip 400f is similar to the light-emitting diode chip 400a of the embodiment of FIG. 7A and FIG. 7B. The components of the light-emitting diode chip 400f and relating description are as provided for the light-emitting diode chip 400a of FIG. 7A and FIG. 7B and are not repeated herein. The difference between the light-emitting diode chip 400f and the light-emitting diode chip 400a is that, an insulating layer 480c of the light-emitting diode chip 400f is disposed on the first-type doped semiconductor layer 112. The portion of the first-type doped semiconductor layer 112 without the insulating layer 480c forms a region R2. In the present embodiment, a first electrode 420b of the light-emitting diode chip 400f includes a bond portion 422b and branched portions 424b extended from the bond portion 422b, and the branched portions 424b are disposed in the region R2. Specifically, in some embodiments, the branched portions 424b disposed in the region R2 and the insulating layer 480c have a suitable gap. Moreover, the insulating layer 480c covers the second-type doped semiconductor layer 116, the light-emitting layer 114, and a portion of the first-type doped semiconductor layer 112. Therefore, the light-emitting diode chip 400f is not readily short-circuited, and better protection is obtained. In the present embodiment, the insulating layer 480c is disposed between the first electrode 420b and the first-type doped semiconductor layer 112, and the first electrode 420b includes the branched portions 424b extended from the bond portion 422b. Therefore, the light-emitting diode chip 400e has a similar effect of increasing luminous efficiency to the light-emitting diode chip 400a of the embodiment of FIG. 7A and FIG. 7B.

FIG. 10C to FIG. 10F are flowcharts of the manufacturing method of the light-emitting diode chip of the embodiment of FIG. 10A. Please refer to FIG. 10C to FIG. 10F. The manufacturing method of the light-emitting diode chip 400f is similar to the manufacturing method of the light-emitting diode chip 400a of FIG. 7C to FIG. 7F. Referring first to FIG. 10C, the manufacturing method of the light-emitting diode chip 400f of the present embodiment includes growing the semiconductor device layer 110 on the substrate SUB. Moreover, referring to FIG. 10D, the current-blocking layer 430 and the current-spreading layer 440 are formed on the second-type doped semiconductor layer 116, and the current-blocking layer 430 is located between the current-spreading layer 440 and the second-type doped semiconductor layer 116. Moreover, referring to FIG. 10E, the insulating layer 480c is formed on the first-type doped semiconductor layer 112. The portion of the first-type doped semiconductor layer 112 without the insulating layer 480c forms the region R2. Specifically, the insulating layer 480c covers the second-type doped semiconductor layer 116, the light-emitting layer 114, and a portion of the first-type doped semiconductor layer 112. Then, referring to FIG. 10F, the first electrode 420 and the second electrode 450 are formed such that the first electrode 420b and the second electrode 450 are respectively electrically connected to the first-type doped semiconductor layer 112 and the current-spreading layer 440 to form the light-emitting diode chip 400f. Specifically, the first electrode 420b of the light-emitting diode chip 400f includes the bond portion 422b and the branched portions 424b extended from the bond portion 422b, and the branched portions 424b are disposed in the region R2.

### Tenth Embodiment

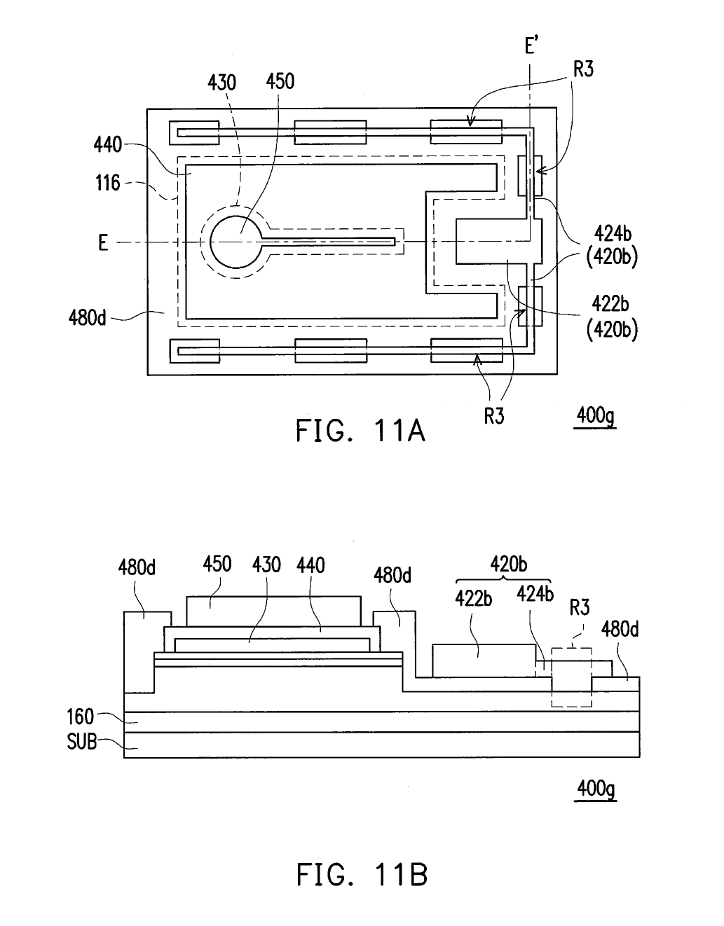

FIG. 11A is a top view of the light-emitting diode chip according to the tenth embodiment of the invention, and FIG. 11B is a cross-sectional view of the light-emitting diode chip of FIG. 11A along line E-E′. Please refer to FIG. 11A and FIG. 11B. In the present embodiment, a light-emitting diode chip 400g is similar to the light-emitting diode chip 400f of the embodiment of FIG. 10A and FIG. 10B. The components of the light-emitting diode chip 400g and relating description are as provided for the light-emitting diode chip 400f of FIG. 10A and FIG. 10B and are not repeated herein. The difference between the light-emitting diode chip 400g and the light-emitting diode chip 400f is that, an insulating layer 480d of the light-emitting diode chip 400g is disposed on the first-type doped semiconductor layer 112, and the portion of the first-type doped semiconductor layer 112 without the insulating layer 480d forms a plurality of regions R3 separated from one another. In the present embodiment, the first electrode 420b of the light-emitting diode chip 400g includes the bond portion 422b and the branched portions 424b extended from the bond portion 422b, the branched portions 424b are disposed in the regions R3, and the regions R3 are arranged along the extending direction of the branched portions 424b. Specifically, in some embodiments, a portion of the branched portions 424b disposed in the regions R3 and the insulating layer 480d have a suitable gap. Moreover, the insulating layer 480d covers the second-type doped semiconductor layer 116, the light-emitting layer 114, and a portion of the first-type doped semiconductor layer 112. Therefore, the light-emitting diode chip 400g is not readily short-circuited, and better protection is obtained. In the present embodiment, the insulating layer 480d is disposed between the first electrode 420b and the first-type doped semiconductor layer 112, and the first electrode 420b includes the branched portions 424b extended from the bond portion 422b. Therefore, the light-emitting diode chip 400g has a similar effect of increasing luminous efficiency to the light-emitting diode chip 400a of the embodiment of FIG. 7A and FIG. 7B. Specifically, since in the locations of the regions R3, the branched portions 424b are in contact with the first-type doped semiconductor layer 112, the regions R3 can be regarded as regions of current collection.

### Eleventh Embodiment

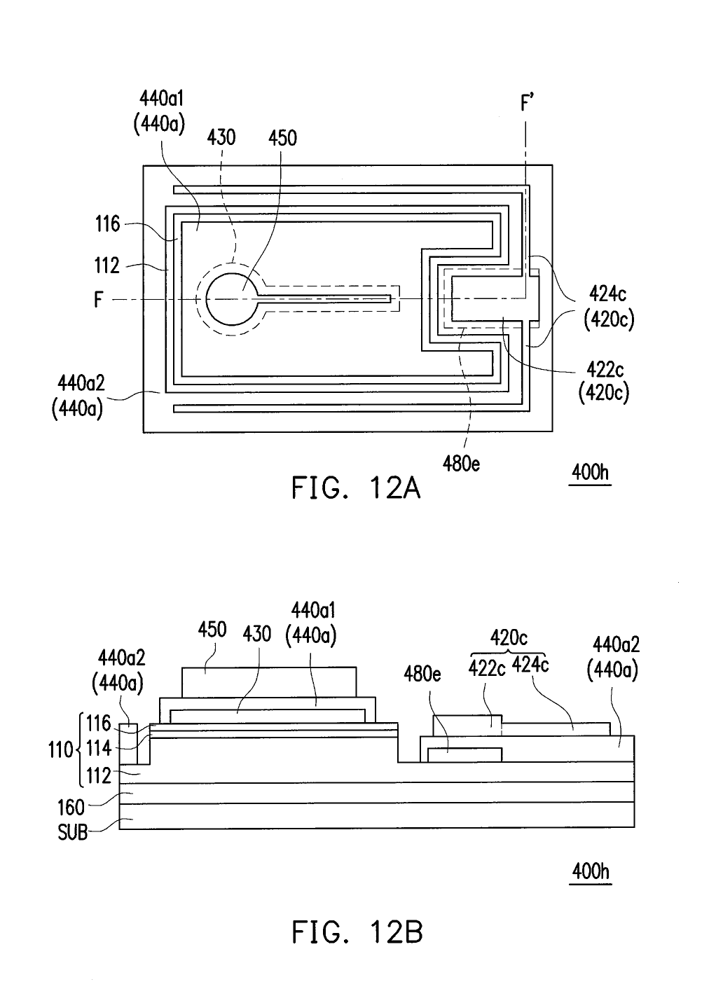

FIG. 12A is a top view of the light-emitting diode chip according to the eleventh embodiment of the invention, and FIG. 12B is a cross-sectional view of the light-emitting diode chip of FIG. 12A along line F-F′. Please refer to FIG. 12A and FIG. 12B. In the present embodiment, a light-emitting diode chip 400h is similar to the light-emitting diode chip 400a of the embodiment of FIG. 7A and FIG. 7B. The components of the light-emitting diode chip 400h and relating description are as provided for the light-emitting diode chip 400a of FIG. 7A and FIG. 7B and are not repeated herein. The difference between the light-emitting diode chip 400h and the light-emitting diode chip 400a is that, a current-spreading layer 440a of the light-emitting diode chip 400h includes a current-spreading layer 440a1 and a current-spreading layer 440a2. The current-spreading layer 440a1 is disposed between the second electrode 450 and the second-type doped semiconductor layer 116, and the current-spreading layer 440a1 covers the current-blocking layer 430. In the present embodiment, the current-spreading layer 440a2 is disposed on the first-type doped semiconductor layer 112 to cover an insulating layer 480e. Moreover, a first electrode 420c includes a bond portion 422c and branched portions 424c extended from the bond portion 422c. The bond portion 422c is disposed above the insulating layer 480e. Specifically, the insulating layer 480e is configured to block electrons from circulating from the bond portion 422c of the first electrode 420c to a first-type doped semiconductor layer 112c. Therefore, the electrons flow directly from the bond portion of the first electrode 420c to the current-spreading layer 440a2, or the electrons flow from the bond portion 422c of the first electrode 420c to the branched portions 424c and then enter the current-spreading layer 440a2. Then, the electrons are circulated to the first-type doped semiconductor layer 112 via the current-spreading layer 440a2. Since the current-spreading layer 440a2 is located between the branched portions 424c and the first-type doped semiconductor layer 112, the region of the first-type doped semiconductor layer 112 receiving the electrons at least includes the region of the first-type doped semiconductor layer 112 corresponding to the branched portions 424c. In the present embodiment, the combination probability of the electrons provided by the first electrode 420c and the electron holes provided by the second electrode 450 is increased to generate more photons, such that the light-emitting diode chip 400h has a similar effect of increasing luminous efficiency to the light-emitting diode chip 400a of the embodiment of FIG. 7A and FIG. 7B.

### Twelfth Embodiment

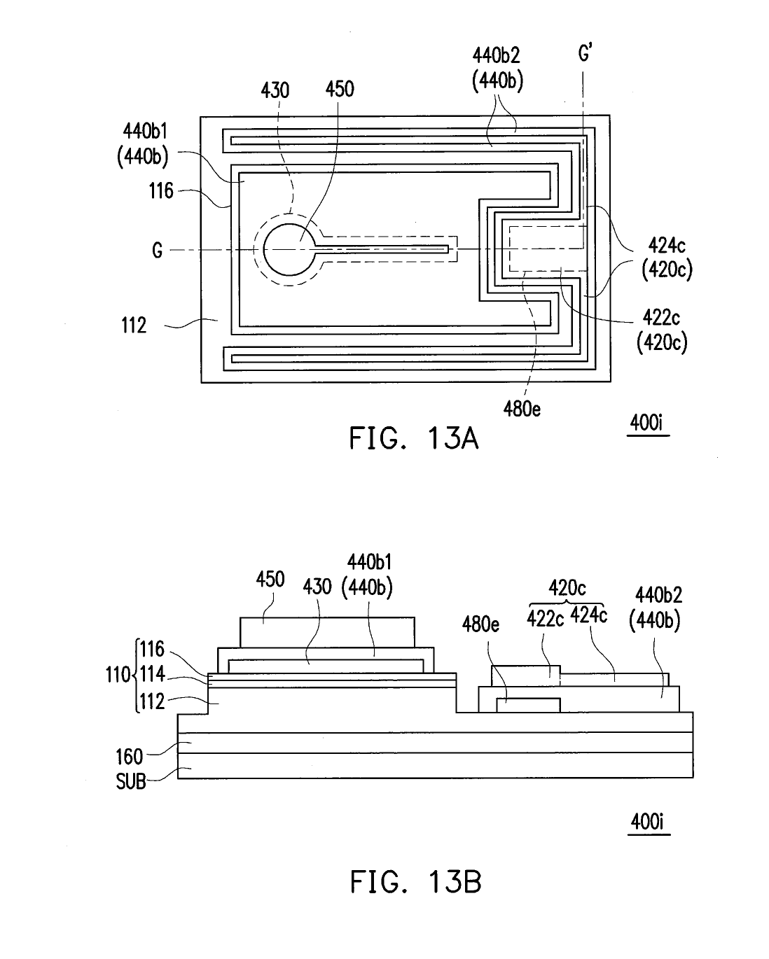

FIG. 13A is a top view of the light-emitting diode chip according to the twelfth embodiment of the invention, and FIG. 13B is a cross-sectional view of the light-emitting diode chip of FIG. 13A along line G-G′. Please refer to FIG. 13A and FIG. 13B. In the present embodiment, a light-emitting diode chip 400i is similar to the light-emitting diode chip 400h of the embodiment of FIG. 12A and FIG. 12B. The components of the light-emitting diode chip 400i and relating description are as provided for the light-emitting diode chip 400h of FIG. 12A and FIG. 12B and are not repeated herein. The difference between the light-emitting diode chip 400i and the light-emitting diode chip 400h is that, the current-spreading layer 440b of the light-emitting diode chip 400i includes a current-spreading layer 440b1 and a current-spreading layer 440b2. The current-spreading layer 440b1 is disposed between the second electrode 450 and the second-type doped semiconductor layer 116, and the current-spreading layer 440b1 covers the current-blocking layer 430. Moreover, the current-spreading layer 440b2 is disposed on the first-type doped semiconductor layer 112 to cover an insulating layer 480e. In the present embodiment, the current-spreading layer 440b2 is disposed between the branched portions 424c and the first-type doped semiconductor layer 112 along the extending direction of the branched portions 424c, and the disposition range of the current-spreading layer 440b2 on the first-type doped semiconductor layer 112 corresponds to a nearby region of the location of the branched portions 424c. Therefore, the region of the first-type doped semiconductor layer 112 receiving the electrons at least includes the region of the first-type doped semiconductor layer 112 corresponding to the branched portions 424c, such that the light-emitting diode chip 400i has a similar effect of increasing the luminous efficiency to the light-emitting diode chip 400h of the embodiment of FIG. 12A and FIG. 12B.

### Thirteenth Embodiment

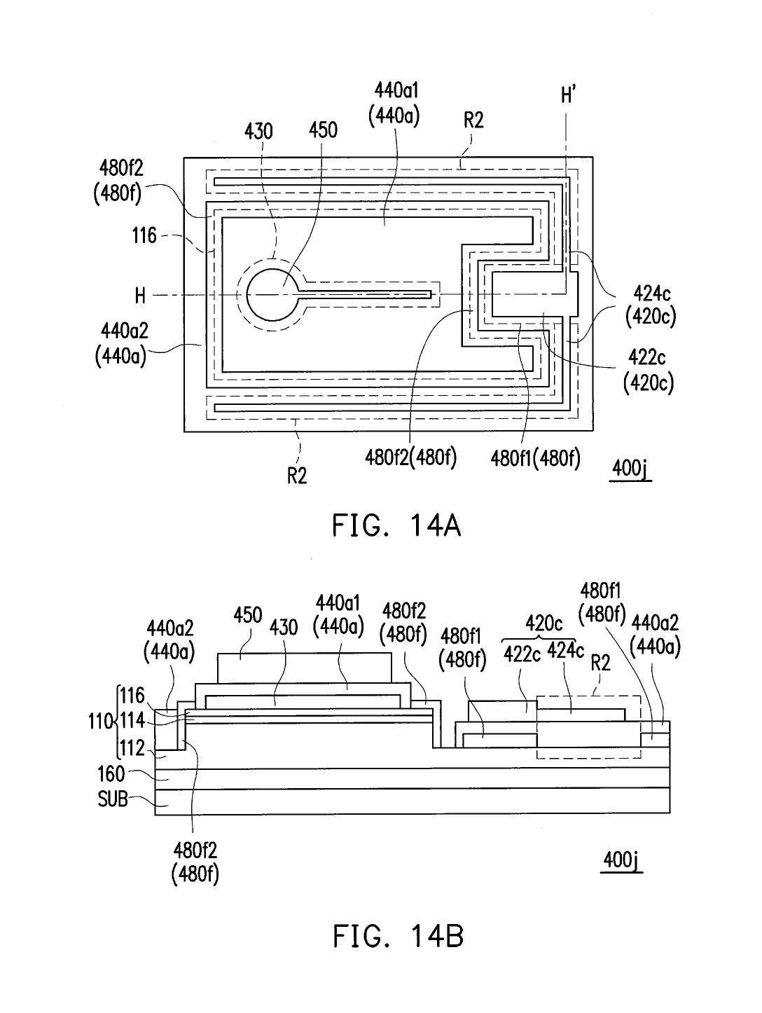

FIG. 14A is a top view of the light-emitting diode chip according to the thirteenth embodiment of the invention, and FIG. 14B is a cross-sectional view of the light-emitting diode chip of FIG. 14A along line H-H′. Please refer to FIG. 14A and FIG. 14B. In the present embodiment, a light-emitting diode chip 400j is similar to the light-emitting diode chip 400h of the embodiment of FIG. 12A and FIG. 12B. The components of the light-emitting diode chip 400j and relating description are as provided for the light-emitting diode chip 400h of FIG. 12A and FIG. 12B and are not repeated herein. The difference between the light-emitting diode chip 400j and the light-emitting diode chip 400h is that, an insulating layer 480f of the light-emitting diode chip 400j includes an insulating layer 480f1 and an insulating layer 480f2, and the current-spreading layer 440a includes the current-spreading layer 440a1 and the current-spreading layer 440a2. The current-spreading layer 440a2 disposed on the first-type doped semiconductor layer 112 to cover the insulating layer 480f1 is a first current-spreading layer, and the current-spreading layer 440a1 disposed on the second-type doped semiconductor layer 116 is a second current-spreading layer. In the present embodiment, the insulating layer 480f2 is disposed between the first current-spreading layer and the second current-spreading layer, and the insulating layer 480f2 electrically insulates the first current-spreading layer and the second current-spreading layer. Specifically, the insulating layer 480f2 is disposed between the current-spreading layer 440a2 and the current-spreading layer 440a1, and the insulating layer 480f2 electrically insulates the current-spreading layer 440a2 and the current-spreading layer 440a1. Therefore, the light-emitting diode chip 400j is not readily short-circuited, and better protection is obtained. In the present embodiment, the current-spreading layer 440a2 is located between the branched portions 424c and the first-type doped semiconductor layer 112, and the insulating layer 480f1 blocks the electrons from the bond portion 422c from entering the first-type doped semiconductor layer 112. Therefore, the light-emitting diode chip 400j has a similar effect of increasing luminous efficiency to the light-emitting diode chip 400h of the embodiment of FIG. 12A and FIG. 12B.

### Fourteenth Embodiment

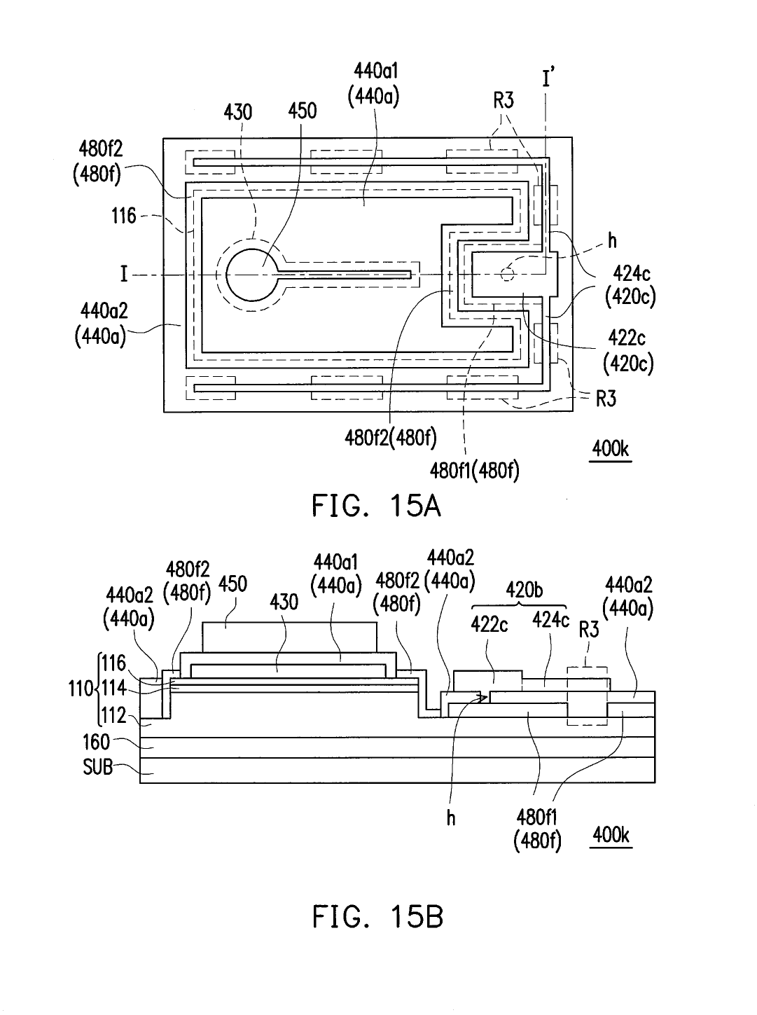

FIG. 15A is a top view of the light-emitting diode chip according to the fourteenth embodiment of the invention, and FIG. 15B is a cross-sectional view of the light-emitting diode chip of FIG. 15A along line I-I′. Please refer to FIG. 15A and FIG. 15B. In the present embodiment, a light-emitting diode chip 400k is similar to the light-emitting diode chip 400j of the embodiment of FIG. 14A and FIG. 14B. The components of the light-emitting diode chip 400k and relating description are as provided for the light-emitting diode chip 400j of FIG. 14A and FIG. 14B and are not repeated herein. The difference between the light-emitting diode chip 400k and the light-emitting diode chip 400j is that, the insulating layer 480fl of the light-emitting diode chip 400k is disposed on the first-type doped semiconductor layer 112, and the portion of the first-type doped semiconductor layer 112 without the insulating layer 480f1 forms a plurality of regions R3 separated from one another. In the present embodiment, since in the locations of the regions R3, the electrons from the branched portions 424c can be transmitted to the first-type doped semiconductor layer 112 via the current-spreading layer 440a2 in contact therewith, the regions R3 can be regarded as regions of current collection. Moreover, in some embodiments, the current-spreading layer 440a2 below the bond portion 422c has a hole h. The bond portion 422c is filled in the hole h and is in contact with the insulating layer 480f1 via the hole h. Specifically, the light-emitting diode chip 400k has a similar effect of increasing luminous efficiency to the light-emitting diode chip 400j of the embodiment of FIG. 14A and FIG. 14B.

### Fifteenth Embodiment

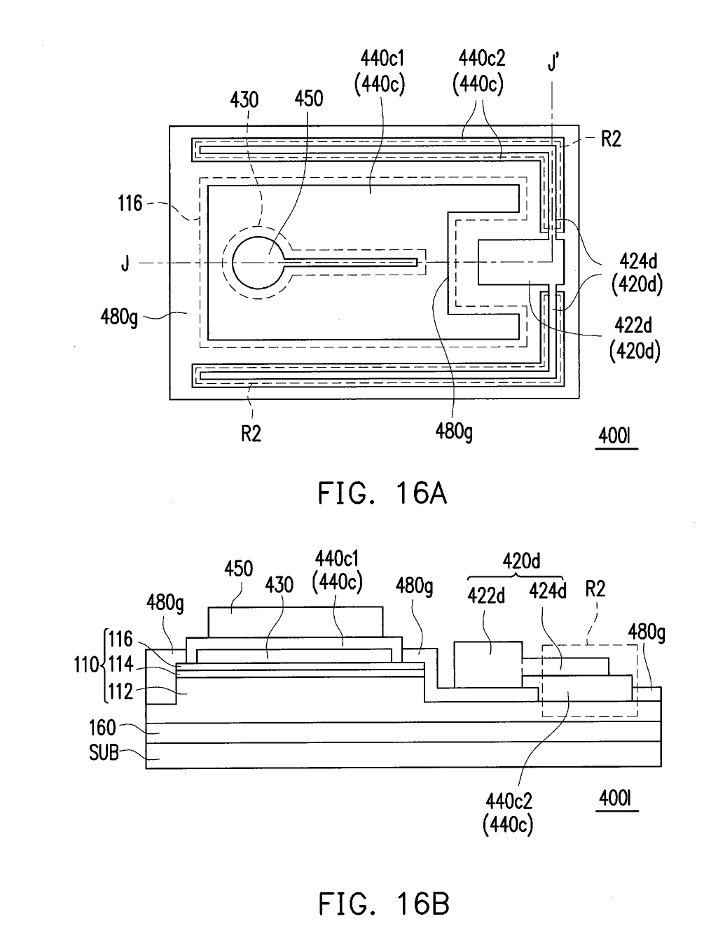

FIG. 16A is a top view of the light-emitting diode chip according to the fifteenth embodiment of the invention, and FIG. 16B is a cross-sectional view of the light-emitting diode chip of FIG. 16A along line J-J′. Please refer to FIG. 16A and FIG. 16B. In the present embodiment, a light-emitting diode chip 400l is similar to the light-emitting diode chip 400f of the embodiment of FIG. 10A and FIG. 10B. The components of the light-emitting diode chip 400l and relating description are as provided for the light-emitting diode chip 400f of FIG. 10A and FIG. 10B and are not repeated herein. The difference between the light-emitting diode chip 400l and the light-emitting diode chip 400f is that, a current-spreading layer 440c of the light-emitting diode chip 400l includes a current-spreading layer 440c1 and a current-spreading layer 440c2, and a first electrode 420d includes a bond portion 422d and branched portions 424d extended from the bond portion 422d. The current-spreading layer 440c2 is disposed in the region R2 without an insulating layer 480g, and the current-spreading layer 440c2 is disposed between the branched portions 424d and the first-type doped semiconductor layer 112. In the present embodiment, the insulating layer 480g covers the second-type doped semiconductor layer 116, the light-emitting layer 114, and a portion of the first-type doped semiconductor layer 112. Therefore, the light-emitting diode chip 400l is not readily short-circuited, and better protection is obtained. Moreover, the light-emitting diode chip 400l has a similar effect of increasing luminous efficiency to the light-emitting diode chip 400f of the embodiment of FIG. 10A and FIG. 10B.

### Sixteenth Embodiment

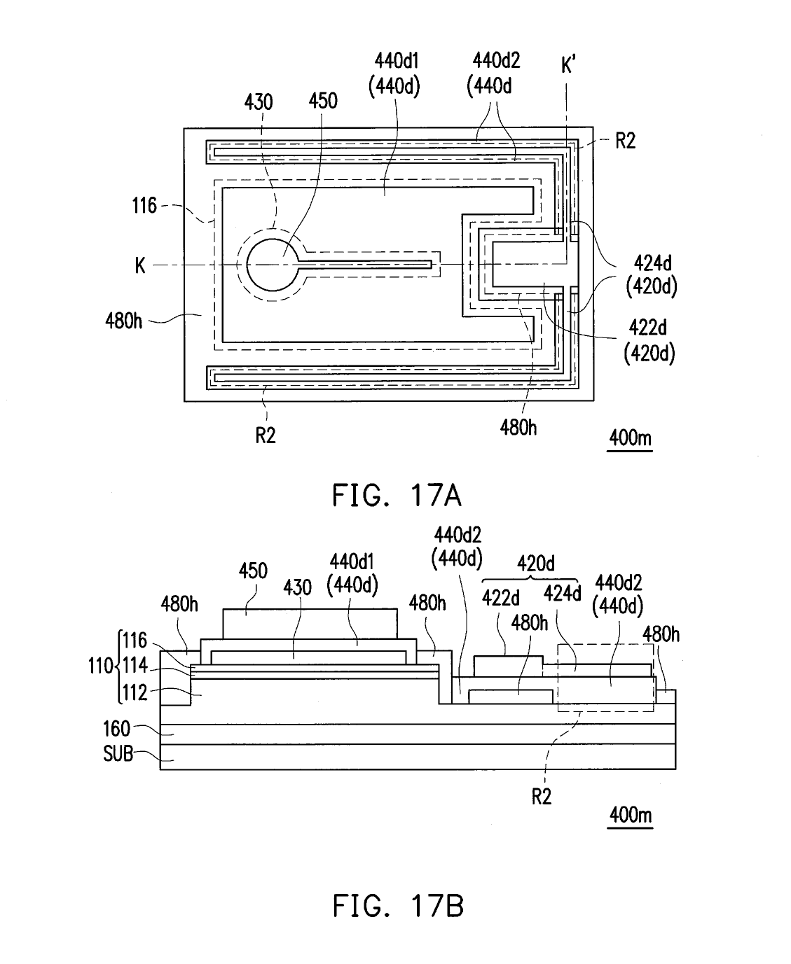

FIG. 17A is a top view of the light-emitting diode chip according to the sixteenth embodiment of the invention, and FIG. 17B is a cross-sectional view of the light-emitting diode chip of FIG. 17A along line K-K′. Please refer to FIG. 17A and FIG. 17B. In the present embodiment, a light-emitting diode chip 400m is similar to the light-emitting diode chip 400l of the embodiment of FIG. 16A and FIG. 16B. The components of the light-emitting diode chip 400m and relating description are as provided for the light-emitting diode chip 400l of FIG. 16A and FIG. 16B and are not repeated herein. The difference between the light-emitting diode chip 400m and the light-emitting diode chip 400l is that, a current-spreading layer 440d of the light-emitting diode chip 400m includes a current-spreading layer 440d1 and a current-spreading layer 440d2. The current-spreading layer 440d2 is disposed in the region R2 without the insulating layer 480g, and the current-spreading layer 440d2 is disposed between the branched portions 424d and the first-type doped semiconductor layer 112. In the present embodiment, the current-spreading layer 440d2 is also disposed between the bond portion 422d and an insulating layer 480h, and the current-spreading layer 440d2 covers the insulating layer 480h. Specifically, the light-emitting diode chip 400m has a similar effect of increasing luminous efficiency to the light-emitting diode chip 400l of the embodiment of FIG. 16A and FIG. 16B.

### Seventeenth Embodiment

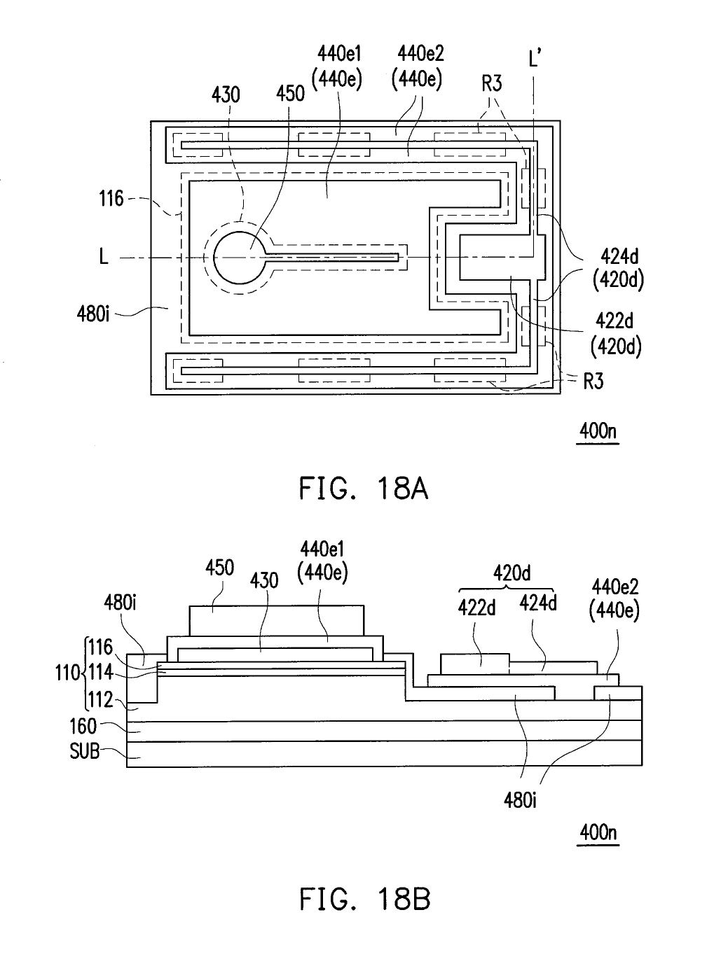

FIG. 18A is a top view of the light-emitting diode chip according to the seventeenth embodiment of the invention, and FIG. 18B is a cross-sectional view of the light-emitting diode chip of FIG. 18A along line L-L′. Please refer to FIG. 18A and FIG. 18B. In the present embodiment, a light-emitting diode chip 400n is similar to the light-emitting diode chip 400m of the embodiment of FIG. 17A and FIG. 17B. The components of the light-emitting diode chip 400n and relating description are as provided for the light-emitting diode chip 400m of FIG. 17A and FIG. 17B and are not repeated herein. The difference between the light-emitting diode chip 400n and the light-emitting diode chip 400m is that, a current-spreading layer 440e of the light-emitting diode chip 400n includes a current-spreading layer 440e1 and a current-spreading layer 440e2. Moreover, an insulating layer 480i of the light-emitting diode chip 400n is disposed on the first-type doped semiconductor layer 112, and the portion of the first-type doped semiconductor layer 112 without the insulating layer 480i forms a plurality of regions R3 separated from one another. In the present embodiment, the first electrode 420d of the light-emitting diode chip 400n includes the bond portion 422d and the branched portions 424d extended from the bond portion 422d, the branched portions 424d are disposed in the regions R3, and the regions R3 are arranged along the extending direction of the branched portions 424d. Moreover, in some embodiments, a portion of the branched portions 424d disposed in the regions R3 and the insulating layer 480i have a suitable gap. Specifically, since in the locations of the regions R3, the electrons from the branched portions 424d can be transmitted to the first-type doped semiconductor layer 112 via the current-spreading layer 440e2 in contact therewith, the regions R3 can be regarded as regions of current collection. Specifically, the light-emitting diode chip 400n has a similar effect of increasing luminous efficiency to the light-emitting diode chip 400k of the embodiment of FIG. 15A and FIG. 15B.

Various implementations of the current-blocking layers and the second electrodes of the light-emitting diode chip 100a, the light-emitting diode chip 100b, the light-emitting diode chip 100c, and the light-emitting diode chip 200 can be at least applied in the light-emitting diode chip 300a, the light-emitting diode chip 300c, the light-emitting diode chip 300d, the light-emitting diode chip 400a, the light-emitting diode chip 400c, the light-emitting diode chip 400d, the light-emitting diode chip 400e, the light-emitting diode chip 400f, the light-emitting diode chip 400g, the light-emitting diode chip 400h, the light-emitting diode chip 400i, the light-emitting diode chip 400j, the light-emitting diode chip 400k, the light-emitting diode chip 400l, the light-emitting diode chip 400m, and the light-emitting diode chip 400n of FIG. 4A to FIG. 18B, and the invention is not limited thereto.

### Eighteenth Embodiment

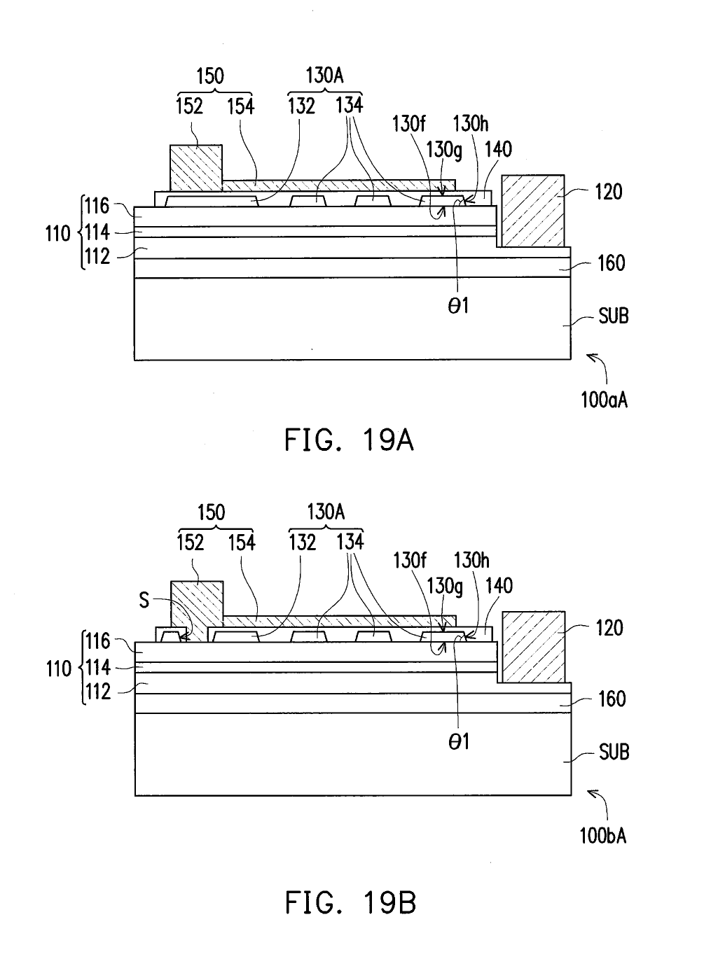

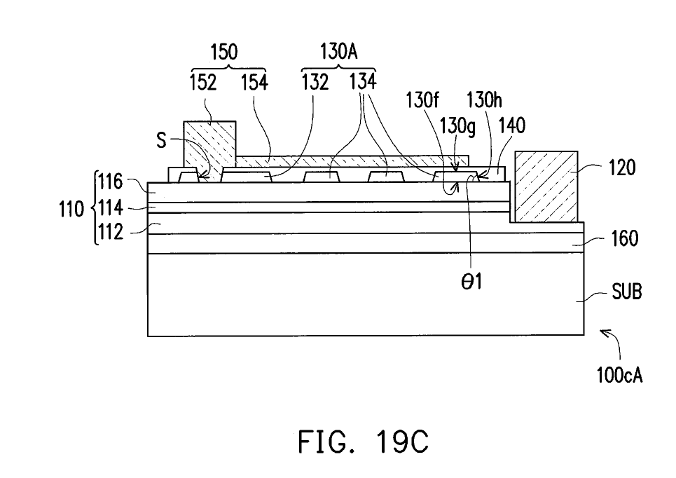

FIG. 19A to FIG. 19C are cross-sectional views the light-emitting diode chips according to the eighteenth embodiment of the invention. The light-emitting diode chips 100aA, 100bA, and 100cA of FIG. 19A to FIG. 19C are similar to the light-emitting diode chips 100a, 100b, and 100c of FIG. 1A to FIG. 1C, respectively. Therefore, same or corresponding components are denoted by same or corresponding symbols. The main difference between the light-emitting diode chips 100aA, 100bA, and 100cA and the light-emitting diode chips 100a, 100b, and 100c lies in that the current-blocking layers 130A of the light-emitting diode chips 100aA, 100bA, and 100cA are different from the current-blocking layer 130 of the light-emitting diode chips 100a, 100b, and 100c. The following paragraphs explain the said difference. Like or corresponding elements and features between the light-emitting diode chips 100aA, 100bA, and 100cA and the light-emitting diode chips 100a, 100b, and 100c may be referred to the previous descriptions based on the symbols in FIG. 19A to FIG. 19C, and will not be repeated in the following.

Please referring to FIG. 19A to FIG. 19C, each of the light-emitting diode chips 100aA, 100bA, and 100cA of the embodiment includes a semiconductor device layer 110, a first electrode 120, a current-blocking layer 130A, a current-spreading layer 140, and a second electrode 150. The semiconductor device layer 110 includes a first-type doped semiconductor layer 112, a light-emitting layer 114, and a second-type doped semiconductor layer 116, wherein the light-emitting layer 114 is located between the first-type doped semiconductor layer 112 and the second-type doped semiconductor layer 116. The first electrode 120 is electrically connected to the first-type doped semiconductor layer 112. The current-blocking layer 130A is disposed on the second-type doped semiconductor layer 116, wherein the current-blocking layer 130A includes a main body 132 and a extending portion 134 extended from the main body 132. The current-blocking layer 130A is sandwiched between the current-spreading layer 140 and the second-type doped semiconductor layer 116. The second electrode 150 is disposed on the current-spreading layer 140 and electrically connected to the second-type doped semiconductor layer 116 through the current-spreading layer 140, wherein the second electrode 150 includes a bond pad 152 and a finger portion 154 extended from the bond pad 152, the bond pad 152 is disposed on the main body 132, the finger portion 154 is disposed on the extending portion 134, and a partial region of the finger portion 154 is not overlapped with the extending portion 134.

Please referring to FIG. 19B, the light-emitting diode chip 100bA of FIG. 19B is similar to the light-emitting diode chip 100aA of FIG. 19A. Therefore, same or corresponding components are denoted by same or corresponding symbols. The main difference between the light-emitting diode chip 100bA and the light-emitting diode chip 100aA of FIG. 19A is that the bond pad 152 penetrates the current-spreading layer 140 and the main body 132, wherein the bond pad 152 contacts the second-type doped semiconductor layer 116, and the current-spreading layer 140 covers a sidewall S of the main body 132 that is penetrated by the bond pad 152.

Please referring to FIG. 19C, the light-emitting diode chip 100cA of FIG. 19C is similar to the light-emitting diode chip 100bA of FIG. 19B. Therefore, same or corresponding components are denoted by same or corresponding symbols. The main difference between the light-emitting diode chip 100cA of FIG. 19C and the light-emitting diode chip 100bA of FIG. 19B lies in that the current-spreading layer 140 does not cover a sidewall S of the main body 132 penetrated by the bond pad 152. In other words, the bond pad 152 penetrating the current-spreading layer 140 and the main body 132 contacts or connects the sidewall S of the main body 132. The light-emitting diode chips 100bA and 100cA and the light-emitting diode chip 100aA have similar effects and benefits and will not be repeated in the following.

In FIG. 19A to FIG. 19C, the current-blocking layer 130A has a first surface 130f facing the semiconductor device layer 110 and a second surface 130g back on to the semiconductor device layer 110. Specifically, the current-blocking layer 130A further includes a first inclined surface 130h connected between the first surface 130f and the second surface 130g. The first inclined surface 130h is tilted with respect to the first surface 130f and the second surface 130g. Furthermore, the first surface 130f contacts the second-type doped semiconductor layer 116 without in contact with the current-spreading layer 140, wherein the second surface 130g and the first inclined surface 130h contact the current-spreading layer 140 without in contact with the second-type doped semiconductor layer 116, the area of the orthographic projection of the first surface 130f on the second-type doped semiconductor layer 116 is greater than the area of the orthographic projection of the second surface 130g on the second-type doped semiconductor layer 116, and the first inclined surface 130h is connected between the edge of the area of the first surface 130f and the edge of the area of the second surface 130g. The first inclined surface 130h and the first surface 130f form an acute angle θ1 within the material of the current-blocking layer 130A. In the embodiment, 10°≤θ1≤80°. Preferably, 30°≤θ1≤50°. However, the invention is not limited thereto.

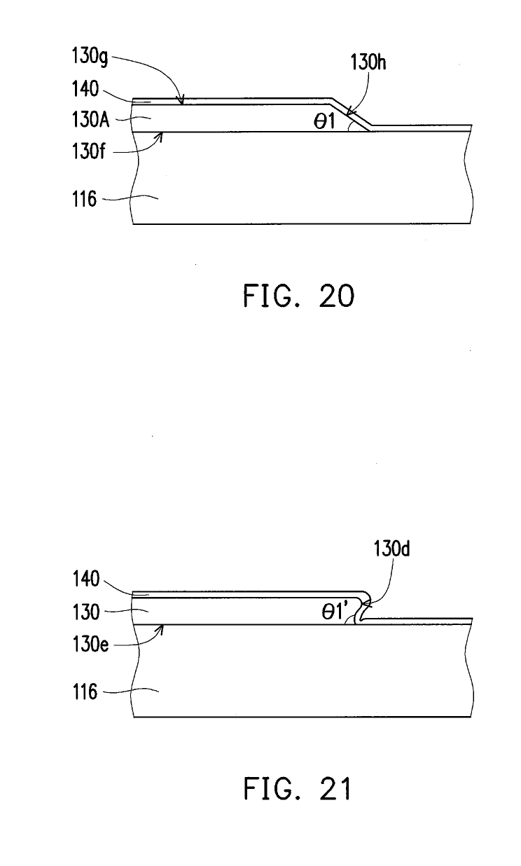

FIG. 20 is an enlarged view of the second-type doped semiconductor layer, the current-blocking layer, and the current-spreading layer of an embodiment of the invention. FIG. 21 is an enlarged view of the second-type doped semiconductor layer, the current-blocking layer, and the current-spreading layer of a comparative example of the invention. Please referring to FIG. 20 and FIG. 21, the sidewall 130d of the current-blocking layer 130 and the bottom surface 130e thereof form an angle θ1′ in the comparative example of FIG. 21, wherein θ1′≥90°. In the case of θ1′≥90°, poor coverage of the current-spreading layer 140 easily occurs near the sidewall 130d when the current-spreading layer 140 is formed to cover current-blocking layer 130. For example, when the current-spreading layer 140 is discontinued at the sidewall 130d, the current-spreading layer 140 is not able to cover the current-blocking layer 130 in a successive manner, and the electrical and optical characteristics and reliability of the light-emitting diode chip are affected. By comparison, please referring to FIG. 20, the current-blocking layer 130A has a first inclined surface 130h in the embodiment. Specifically, the first inclined surface 130h and the first surface 130f form an acute angle θ1 within the material of the current-spreading layer 130A. In the case of θ1 smaller than 90°, the coverage of the current-spreading layer 140 near the first inclined surface 130h is good when the current-spreading layer 140 is formed to cover the current-blocking layer 130A, so that the electrical and optical characteristics and reliability of the light-emitting diode chip 100aA are ensured and even improved. For example, when the coverage of the current-spreading layer 140 near the first inclined surface 130h is good, the driving voltage of the light-emitting diode chip 100aA can be reduced, the uniformity of the current density and the brightness of the light-emitting diode chip 100aA can be increased, and the heat concentration effect in a particular region can be mitigated. In addition, the stability of the manufacturing process of the layers (for example, second electrode 150) subsequently formed on the current-spreading layer 140 can be improved when the coverage of the current-spreading layer 140 is good.

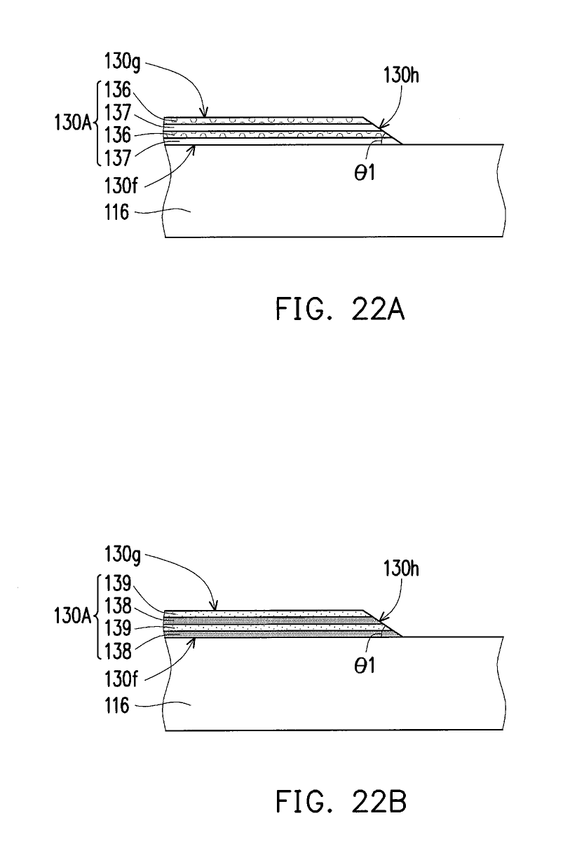

FIG. 22A is an enlarged view of the current-blocking layer of an embodiment of the invention. Please referring to FIG. 22A, the current-blocking layer 130A can be a stacked structure of multiple layers in the embodiment. Specifically, the current-blocking layer 130A includes at least one first current-blocking sub-layer 136 stacked with at least one second current-blocking sub-layer 137. For example, the plurality of first current-blocking sub-layers 136 and the plurality of second current-blocking sub-layers 137 can be stacked alternately. The first current-blocking sub-layer 136 is different from the second current-blocking sub-layer 137 so that an interface exists between those two layers. In the embodiment, the material of the first current-blocking sub-layer 136 can be different from the material of the second current-blocking sub-layer 137. Specifically, the refractive index of the first current-blocking sub-layer 136 can be different from the refractive index of the second current-blocking sub-layer 137. Under the configuration of different refractive indexes, the stack of the first current-blocking sub-layer 136 and the second current-blocking sub-layer 137 can form a Distributed Bragg Reflector (DBR). Please referring to FIG. 19A and FIG. 22A, the light beam emitted by the light-emitting layer 114 and traveling toward the second electrode 150 can be reflected to other places by the Distributed Bragg Reflector, so that the light beam emitted by the light-emitting layer 114 is not easily blocked by the second electrode 150 and capable of emitting out at other places consequently, and the brightness of the light-emitting diode chip is improved. Similarly, the design of FIG. 22A is applied to FIG. 19B and FIG. 19C, so the current-blocking layer 130A can provide the effect of the Distributed Bragg Reflector and increase the brightness of the light-emitting diode chips 100bA and 100cA.

When the first and second current-blocking sub-layers 136, 137 of different materials are used to produce the current-blocking layer 130A, the lift-off method, for example, can be used to fabricate the current-blocking layer 130A having the first inclined surface 130h, but the present invention is not limited thereto. In other embodiments, other methods can be used to produce the current-blocking layer 130A. In the embodiment, one of the first current-blocking sub-layer 136 and the second current-blocking sub-layer 137 can be TiO₂, wherein the other one of the first current-blocking sub-layer 136 and the second current-blocking sub-layer 137 can be SiO₂. However, the invention is not limited thereto. In other embodiments, other suitable materials can be used to form the first current-blocking sub-layer 136 and the second current-blocking sub-layer 137. In addition, the materials of the first current-blocking sub-layer 136 and the second current-blocking sub-layer 137 are not necessary to be different. FIG. 22B is used as an example for illustration in the following paragraphs.

FIG. 22B is an enlarged view of the current-blocking layer of another embodiment of the invention. Please referring to FIG. 22B, the current-blocking layer 130A includes at least one first current-blocking sub-layer 138 stacked with at least one second current-blocking sub-layer 139. The plurality of first current-blocking sub-layers 138 and the plurality of second current-blocking sub-layers 139 can be stacked alternately. An interface exists between the first current-blocking sub-layer 138 and the second current-blocking sub-layer 139. Specifically, the material of the first current-blocking sub-layer 138 can be the same with the material of the second current-blocking sub-layer 139, but the density of the first current-blocking sub-layer 138 is larger than the density of the second current-blocking sub-layer 139. In the embodiment, the first and second current-blocking sub-layers 138, 139 of different densities can be formed by controlling the manufacturing parameters (temperature, pressure, processing time, etc., for example). When the first and second current-blocking sub-layers 138, 139 of same material but different densities are used to construct the current-blocking layer 130A, the etching process can be used to pattern the first and second current-blocking sub-layers 138, 139. Because the densities of the first and second current-blocking sub-layers 138, 139 are different, the remaining area of the first current-blocking sub-layer 138 with a higher density is larger, while the remaining area of the second current-blocking sub-layer 139 with a lower density is smaller when the first and second current-blocking sub-layers 138, 139 are etched simultaneously. In other words, the projection length of the remaining area of the first current-blocking sub-layer 138 with a higher density projected onto the second-type doped semiconductor layer 116 is larger, while the projection length of the remaining area of the second current-blocking sub-layer 139 with a lower density projected onto the second-type doped semiconductor layer 116 is smaller, so as to make the structure having the first inclined surface 130h formed in the current-blocking layer 130A. It should be noted that the current-blocking layer 130A including multiple layers is used as an example for illustration in the foregoing paragraphs, but the current-blocking layer 130A is not limited to include multiple layers in the present invention. In other embodiments, the current-blocking layer 130A can also merely have a single layer. In other words, a single-layer or multi-layer current-blocking layer 130A falls within the scope of the present invention as long as it has the first inclined surface 130h.

### Nineteenth Embodiment

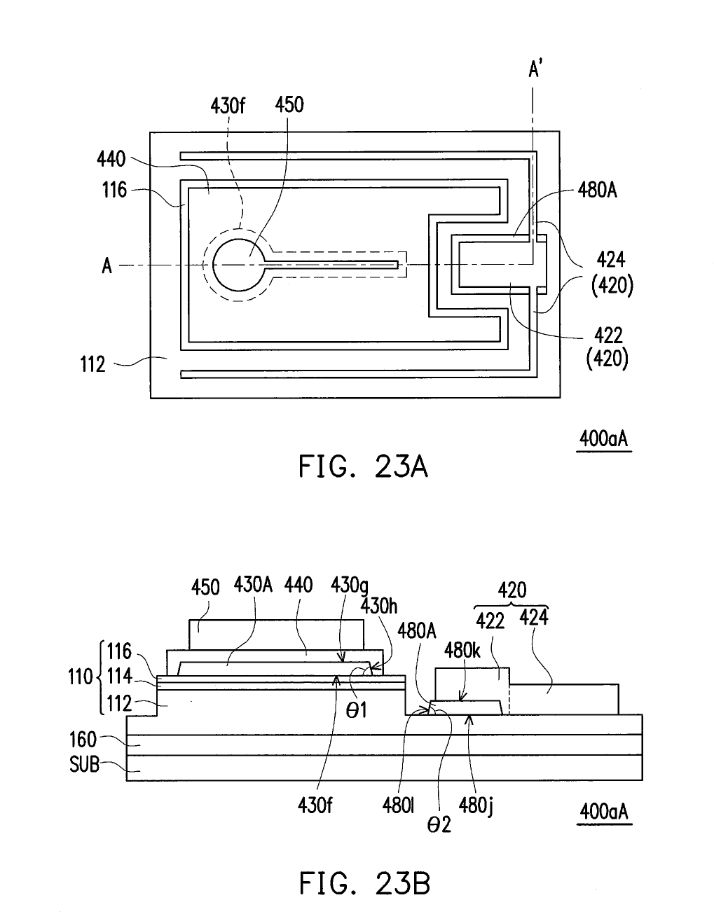

FIG. 23A is a top view of the light-emitting diode chip according to the nineteenth embodiment of the invention, wherein FIG. 23B is a cross-sectional view of the light-emitting diode chip of FIG. 23A along line A-A′. The light-emitting diode chip 400aA of FIG. 23A and FIG. 23B is similar to the light-emitting diode chip 400a of FIG. 7A and FIG. 7B. Therefore, same or corresponding components are denoted by same or corresponding symbols. The main difference between light-emitting diode chip 400aA and light-emitting diode chip 400a is that the current-blocking layer 430A and the insulating layer 480A of the light-emitting diode chip 400aA are different from the current-blocking layer 430 and the insulating layer 480A of the light-emitting diode chip 400a. The following paragraphs explain the said difference. For the same or corresponding features between light-emitting diode chip 400aA and light-emitting diode chip 400a, please referring to the foregoing descriptions according to the symbols of FIG. 23A and FIG. 23B and will not be repeated herein.

Please referring to FIGS. 23A and 23B, the light-emitting diode chip 400aA is similar to the light-emitting diode chip 100aA of FIG. 19A in the embodiment. Specifically, the light-emitting diode chip 400aA includes a semiconductor device layer 110, a current-spreading layer 440, a first electrode 420, an insulating layer 480A, and a second electrode 450. The semiconductor device layer 110 includes a first-type doped semiconductor layer 112, a light-emitting layer 114, and a second-type doped semiconductor layer 116. The light-emitting layer 114 is located between the first-type doped semiconductor layer 112 and the second-type doped semiconductor layer 116. In the embodiment, the current-blocking layer 440 is disposed on the second-type doped semiconductor layer 116. The first electrode 420 is electrically connected to the first-type doped semiconductor layer 112, wherein the insulating layer 480A is disposed between the first electrode 420 and the first-type doped semiconductor layer 112. In addition, the second electrode 450 is disposed on the current-spreading layer 440 and is electrically connected to the second-type doped semiconductor layer 116 through the current-spreading layer 440.

The light-emitting diode chip 400aA further includes the current-blocking layer 430A disposed between the current-spreading layer 440 and the second-type doped semiconductor layer 116. What is different from the light-emitting diode chip 400a is that the current-blocking layer 430A can have a structure of the current-blocking layer 130A of the light-emitting diode chip 100aA of FIG. 19A. In other words, the current-blocking layer 430A can have a first surface 430f facing the semiconductor device layer 110, a second surface 430g back on to the semiconductor device layer 110, and a first inclined surface 430h connected between the first surface 430f and the second surface 430g. The first inclined surface 430h is tilted with respect to the first surface 430f and the second surface 430g. The first inclined surface 430h and the first surface 430f form an acute angle θ1 within the material of the current-blocking layer 430A. In addition, the structure of the current-blocking layer 430A can be a multi-layer structure of FIG. 22A, a multi-layer structure of FIG. 22B or a single layer structure. Regarding the description of the detailed structure of the current-blocking layer 430A having multiple layers, please refer to the foregoing descriptions according to FIG. 22A and FIG. 22B. In addition, the components, disposition of the components and the related description of the light-emitting diode chip 400aA may refer to the descriptions with respect to the light-emitting diode chip 100aA in FIG. 19A, and will not be repeated herein.

The first electrode 420 includes a bond portion 422 and a branched portion 424 extended from the bond portion 422. Specifically, the bond portion 422 is disposed on the insulating layer 480A. The insulating layer 480A is used to block the electrons flowing from the bond portion 422 of the first electrode 420 to the first-type doped semiconductor layer 112, make the electrons flow through the branched portion 424 from the bond portion 422 of the first electrode 420, and make the electrons flow to first-type doped semiconductor layer 112 through the branched portion 424. In the embodiment, because these branched portions 424 are extended to a location farther from the bond portion 422, the electrons generated by driving the light-emitting diode chip 400aA may flow through the branched portion 424 from the bond portion 422. In addition, by being spread to a location farther from the bond portion 422, the electrons can flow into the portion of the first-type doped semiconductor layer 112 corresponding to the location farther from the bond portion 422. Specifically, the electrons generated by driving the light-emitting diode chip 400aA flow into the corresponding portion of the first-type doped semiconductor layer 112 through the branched portion 424 distributed on the first-type doped semiconductor layer 112. Therefore, the region of the first-type doped semiconductor layer 112 receiving the electrons at least includes the region where the branched portion 424 contacts the first-type doped semiconductor layer 112, which facilitates to increase the rejoining probability of the electrons provided by the first electrode 420 and the electron holes provided by the second electrode 450, so as to improve the light emitting efficiency of the light-emitting diode chip 400aA.

In the embodiment, the insulating layer 480A can be a dielectric layer, for example, the materials of the insulating layer 480A include dielectric materials like SiOₓ and SiNₓ. In some embodiments, the materials of the insulating layer 480A can also be dielectric materials of other types, wherein the materials of the insulating layer 480A can be the same or different from the materials of the current-blocking layer 430A, the present invention is not limited thereto. What is different from the insulating layer 480 of FIGS. 7A and 7B is that the insulating layer 480A has a third surface 480j facing the first-type doped semiconductor layer 112 of the semiconductor device layer 110, a fourth surface 480k back on to the first-type doped semiconductor layer 112 of the semiconductor device layer 110, and a second inclined surface 480l. The second inclined surface 480l is connected between the third surface 480j and the fourth surface 480k. The second inclined surface 480l is tilted with respect to the third surface 480j and the fourth surface 480k. Specifically, the third surface 480j contacts the first-type doped semiconductor layer 112 without in contact with the first electrode 420, wherein the fourth surface 480k contacts the first electrode 420 without in contact with the first-type doped semiconductor layer 112, the area of the orthographic projection of the third surface 480j on the first-type doped semiconductor layer 112 is larger than the area of the orthographic projection of the fourth surface 480k on the first-type doped semiconductor layer 112, and the second inclined surface 480l is connected between the edge of the area of the third surface 480j and the edge of the area of the fourth surface 480k. The second inclined surface 480l and the third surface 480j form an acute angle θ2 within the material of the insulating layer 480A. In the embodiment, 10°≤θ2≤80°. Preferably, 30°≤θ2≤50°. However, the invention is not limited thereto. Similarly, because the insulating layer 480A has the second inclined surface 480l, the second electrode 420 can be well coated on the insulating layer 480A, which helps to improve the performance of the light-emitting diode chip 400aA when the second electrode 420 covers the insulating layer 480A.

### Twentieth Embodiment

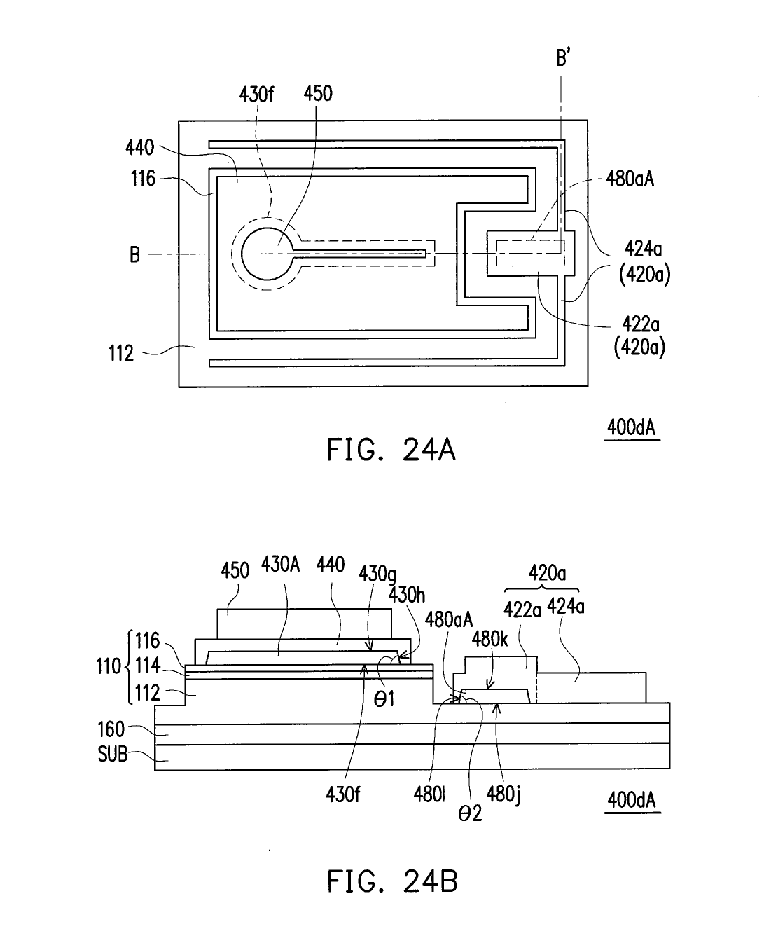

FIG. 24A is a top view of the light-emitting diode chip according to the twentieth embodiment of the invention, wherein FIG. 24B is a cross-sectional view of the light-emitting diode chip of FIG. 24A along line B-B′. Please referring to FIG. 24A and FIG. 24B, in the embodiment, the light-emitting diode chip 400dA is similar to the light-emitting diode chip 400aA of FIG. 23A and FIG. 23B. Therefore, same or corresponding components are denoted by same or corresponding symbols. The components and the related description of the light-emitting diode chip 400dA may refer to the light-emitting diode chip 400aA in FIG. 23A and FIG. 23B, and will not be repeated herein. The difference between the light-emitting diode chip 400dA and the light-emitting diode chip 400aA is substantially similar to the difference between the light-emitting diode chip 400d and the light-emitting diode chip 400a. Specifically, the first electrode 420a of the light-emitting diode chip 400dA includes a bond portion 422a and a branched portion 424a extended from the bond portion 422a. Specifically, the bond portion 422a is disposed on the insulating layer 480aA, wherein the bond portion 422a covers the insulating layer 480aA.

The insulating layer 480aA has a third surface 480j facing the first-type doped semiconductor layer 112 of the semiconductor device layer 110, a fourth surface 480k back on to the first-type doped semiconductor layer 112 of the semiconductor device layer 110, and a second inclined surface 480l. The second inclined surface 480l is connected between the third surface 480j and the fourth surface 480k. The second inclined surface 480l is tilted with respect to the third surface 480j and the fourth surface 480k. Specifically, the third surface 480j contacts the first-type doped semiconductor layer 112 without in contact with the first electrode 420, wherein the fourth surface 480k contacts the first electrode 420 without in contact with the first-type doped semiconductor layer 112, the area of the orthographic projection of the third surface 480j on the first-type doped semiconductor layer 112 is larger than the area of the orthographic projection of the fourth surface 480k on the first-type doped semiconductor layer 112, and the second inclined surface 480l is connected between the edge of the area of the third surface 480j and the edge of the area of the fourth surface 480k.

In the embodiment, the insulating layer 480aA is disposed between the first electrode 420a and the first-type doped semiconductor layer 112, wherein the first electrode 420a includes a branched portion 424a extended from the bond portion 422a. Therefore, in the light-emitting diode chip 400dA, the rejoining probability of the electrons provided by the first electrode 420a and the electron holes provided by the second electrode 450 is increased, wherein more photons are produced, so as to make the luminescence efficiency of the light-emitting diode chip 400dA more improved in comparison with the luminescence efficiency of the light-emitting diode chip 400aA of the embodiments of FIG. 23A and FIG. 23B.

### Twenty First Embodiment

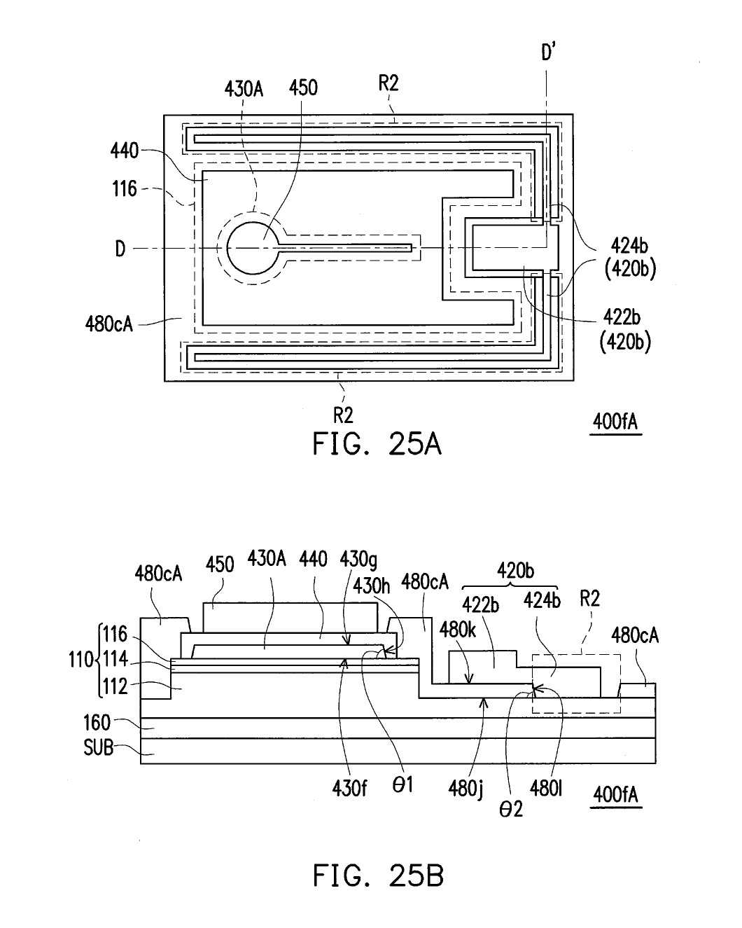

FIG. 25A is a top view of the light-emitting diode chip according to the twenty first embodiment of the invention, wherein FIG. 25B is a cross-sectional view of the light-emitting diode chip of FIG. 25A along line D-D′. Please referring to FIG. 25A and FIG. 25B, in the embodiment, the light-emitting diode chip 400fA is similar to the light-emitting diode chip 400aA of FIG. 23A and FIG. 23B. Therefore, same or corresponding components are denoted by same or corresponding symbols. The components and the related description of the light-emitting diode chip 400fA may refer to the light-emitting diode chip 400aA in FIG. 23B, and will not be repeated herein. The difference between the light-emitting diode chip 400fA and the light-emitting diode chip 400aA is substantially similar to the difference between the light-emitting diode chip 400f and the light-emitting diode chip 400a. Specifically, the insulating layer 480cA of the light-emitting diode chip 400fA is disposed on the first-type doped semiconductor layer 112. The portion of the first-type doped semiconductor layer 112 where the insulating layer 480cA is not disposed forms a region R2. In the embodiment, the first electrode 420b of the light-emitting diode chip 400fA includes a bond portion 422b and a branched portion 424b extended from the bond portion 422b, in which the branched portion 424b is disposed in the region R2.

The insulating layer 480cA has a third surface 480j facing the first-type doped semiconductor layer 112 of the semiconductor device layer 110, a fourth surface 480k back on to the first-type doped semiconductor layer 112 of the semiconductor device layer 110, and a second inclined surface 480l. The second inclined surface 480l is connected between the third surface 480j and the fourth surface 480k. The second inclined surface 480l is tilted with respect to the third surface 480j and the fourth surface 480k. Specifically, the third surface 480j contacts the first-type doped semiconductor layer 112 without in contact with the first electrode 420, wherein the fourth surface 480k contacts the first electrode 420 without in contact with the first-type doped semiconductor layer 112, the area of the orthographic projection of the third surface 480j on the first-type doped semiconductor layer 112 is larger than the area of the orthographic projection of the fourth surface 480k on the first-type doped semiconductor layer 112, and the second inclined surface 480l is connected between the edge of the area of the third surface 480j and the edge of the area of the fourth surface 480k.

Specifically, there is an appropriate gap between the branched portion 424b disposed in region R2 and the insulating layer 480cA in some embodiments. In addition, the insulating layer 480cA covers the second-type doped semiconductor layer 116, the light-emitting layer 114, and part of the first-type doped semiconductor layer 112. Therefore, short circuit can be less prone to occur in the light-emitting diode chip 400fA and the light-emitting diode chip 400fA gets better protection. In the embodiment, the insulating layer 480cA is disposed between the first electrode 420b and the first-type doped semiconductor layer 112, wherein the first electrode 420b includes a branched portion 424b extended from the bond portion 422b. Therefore, the light-emitting diode chip 400fA has an effect of improving the luminescence efficiency similar to the light-emitting diode chip 400aA in the embodiments of FIG. 23A and FIG. 23B.

### Twenty Second Embodiment

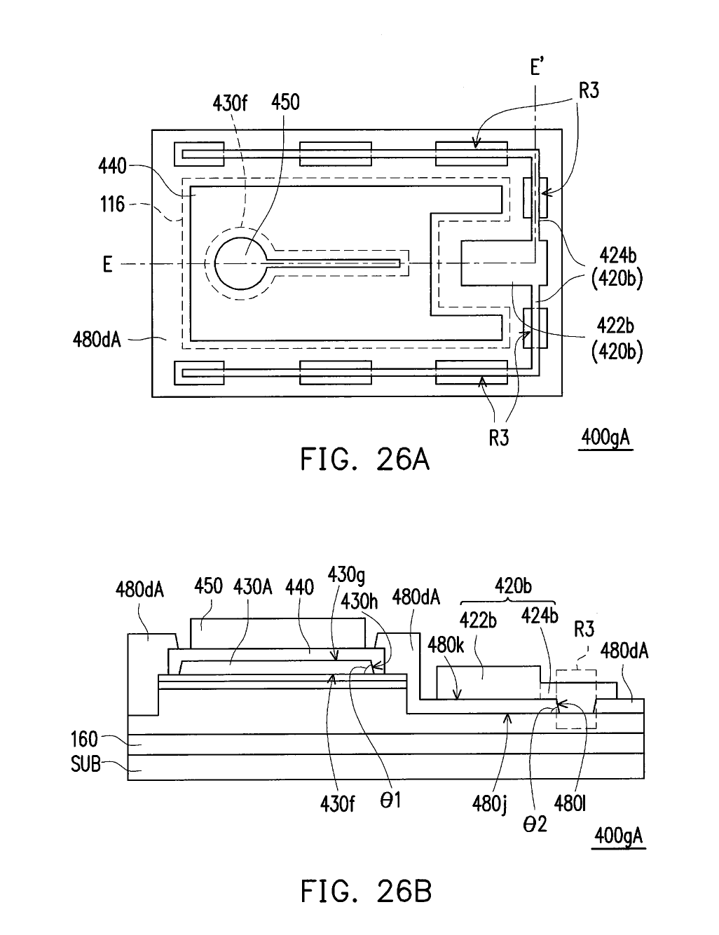

FIG. 26A is a top view of the light-emitting diode chip according to the twenty second embodiment of the invention, wherein FIG. 26B is a cross-sectional view of the light-emitting diode chip of FIG. 26A along line E-E′. Please referring to FIG. 26A and FIG. 26B, in the embodiment, the light-emitting diode chip 400gA is similar to the light-emitting diode chip 400fA in the embodiments of FIG. 25A and FIG. 25B. Therefore, same or corresponding components are denoted by same or corresponding symbols. The components and the related description of the light-emitting diode chip 400gA may refer to the light-emitting diode chip 400fA in FIG. 25A and FIG. 25B, and will not be repeated herein. The difference between the light-emitting diode chip 400gA and the light-emitting diode chip 400fA is substantially similar to the difference between the light-emitting diode chip 400g and the light-emitting diode chip 400f. Specifically, the insulating layer 480dA of the light-emitting diode chip 400gA is disposed on the first-type doped semiconductor layer 112, wherein the portion of the first-type doped semiconductor layer 112 where the insulating layer 480dA is not disposed forms a plurality of regions R3 separating from each other. In the embodiment, the first electrode 420b of the light-emitting diode chip 400gA includes a bond portion 422b and a branched portion 424b extended from the bond portion 422b, wherein the plurality of regions R3 are arranged along the extending direction of the branched portion 424b. Specifically, there is an appropriate gap between a partial region of the branched portion 424b disposed in the regions R3 and the insulating layer 480dA in some embodiments.

The insulating layer 480dA has a third surface 480j facing the first-type doped semiconductor layer 112 of the semiconductor device layer 110, a fourth surface 480k back on to the first-type doped semiconductor layer 112 of the semiconductor device layer 110, and a second inclined surface 480l. The second inclined surface 480l is connected between the third surface 480j and the fourth surface 480k. The second inclined surface 480l is tilted with respect to the third surface 480j and the fourth surface 480k. Specifically, the third surface 480j contacts the first-type doped semiconductor layer 112 without in contact with the first electrode 420, wherein the fourth surface 480k contacts the first electrode 420 without in contact with the first-type doped semiconductor layer 112, the area of the orthographic projection of the third surface 480j on the first-type doped semiconductor layer 112 is larger than the area of the orthographic projection of the fourth surface 480k on the first-type doped semiconductor layer 112, and the second inclined surface 480l is connected between the edge of the area of the third surface 480j and the edge of the area of the fourth surface 480k.

In addition, the insulating layer 480dA covers the second-type doped semiconductor layer 116, the light-emitting layer 114, and a partial region of the first-type doped semiconductor layer 112. Therefore, short circuit can be less prone to occur in the light-emitting diode chip 400gA and the light-emitting diode chip 400gA gets better protection. In the embodiment, the insulating layer 480dA is disposed between the first electrode 420b and the first-type doped semiconductor layer 112, wherein the first electrode 420b includes a branched portion 424b extended or protruding from the bond portion 422b. Therefore, the light-emitting diode chip 400g has an improved the luminescence efficiency similar to the light-emitting diode chip 400aA in the embodiments of FIG. 23A and FIG. 23B. Specifically, because the branched portion 424b contacts the first-type doped semiconductor layer 112 in the place where the regions R3 are located, the regions R3 can be regarded as the region where the current concentrates.

Based on the above, the current-blocking layer of the light-emitting diode chip has an inclined surface in an embodiment of the present invention. In such a way, the coverage of the current-spreading layer near the inclined surface can be good when the current-spreading layer is designed to cover the current-blocking layer, so that the electrical and optical characteristics and reliability of the light-emitting diode chip are improved. In addition, the light-emitting diode chip includes a current-spreading layer in another embodiment of the present invention. In such a way, the light beam emitted by the light-emitting layer and traveling toward the electrode can be reflected to other places by the current-spreading layer, so that the light beam emitted by the light-emitting layer is not easily blocked by the shielding electrode and capable of emitting out at other places consequently, and the brightness of the light-emitting diode chip is improved.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

What is claimed is:

1. A light-emitting diode chip, comprising:
a semiconductor device layer comprising a first-type doped semiconductor layer, a light-emitting layer, and a second-type doped semiconductor layer, wherein the light-emitting layer is located between the first-type doped semiconductor layer and the second-type doped semiconductor layer;
a first electrode electrically connected to the first-type doped semiconductor layer;
a first current-blocking layer disposed on the second-type doped semiconductor layer and exposing a portion of the second-type doped semiconductor layer, and the first current-blocking layer comprises a main body and an extension portion extended from the main body;
a current-spreading layer disposed on the first current-blocking layer and extending over an edge of the first current-blocking layer to cover at least a portion of the exposed second-type doped semiconductor layer; and
a second electrode disposed on the current-spreading layer and electrically connected to the second-type doped semiconductor layer through the current-spreading layer, wherein the second electrode comprises a bonding pad and a finger portion extended from the bonding pad, the bonding pad and the finger portion of the second electrode are aligned with the main portion and the extension portion of the first current-blocking layer respectively and an entire footprint of the second electrode is disposed within an area of the first current-blocking layer.

2. The light-emitting diode chip of claim 1, further a second current-blocking layer disposed between the first electrode and the first-type doped semiconductor layer, and the first electrode further comprising a bonding portion and at least one finger portion extended from the bonding pad, wherein an footprint of the bonding portion of the first electrode is disposed within an area of the second current-blocking layer and the finger portion of the first electrode is direct in contact with the first-type doped semiconductor layer, and the finger portion of the first electrode has a part climbing over an edge of the second current-blocking layer to connect the bonding portion of the first electrode.

3. The light-emitting diode chip of claim 1, wherein the first current-blocking layer has an inclined lateral surface including an acute angle with respect to the second-type doped semiconductor layer.

4. The light-emitting diode chip of claim 2, wherein the second current-blocking layer has an inclined lateral surface including an acute angle with respect to the first-type doped semiconductor layer.
